(19) United States
(12) Patent Application Publication
(10) Pub. No.: US 2005/0048772 A1
(43) Pub. Date: Mar. 3, 2005

(54) Bond pad techniques for integrated circuits

(75) Inventor: Judon Tony Pan, Saratoga, CA (US)

Correspondence Address: PATENT COUNSEL;APPLIED MATERIALS, INC., Legal Affairs Department, P.O.BOX 450A, Santa Clara, CA, 95052, US

(73) Assignee: Applied Materials, Inc.

(21) Appl. No.: 10/654,240

(22) Filed: Sep. 2, 2003

(51) Int. Cl. H01L 21/44

(52) U.S. Cl. 438/672

(57) ABSTRACT

The present invention provides methods for fabricating bond pads that can be employed for fabricating solder bumps and wire bonds, as well as structures containing the bond pads. Bond pads of the present invention include a contiguous interconnect line, fabricated in a dielectric layer such that the bond pad and line are exposed. A passivation layer is then deposited on the dielectric layer, the bond pad and the interconnect line. A passivation hole is etched in the passivation layer such that the hole exposes at least a portion of the bond pad. The bond pad and contiguous interconnect line can be provided with a metal overcoat layer on the top surface of the bond pad, and a barrier/seed layer on the bottom and side surfaces of the bond pad and the contiguous interconnect line.

### FIELD OF THE INVENTION

The present invention relates to integrated circuit fabricating techniques and materials for forming bond pads, bond pad stacks and solder bumps for fabricating external connections to integrated circuits.

### BACKGROUND OF THE INVENTION

A semiconductor device such as an IC (integrated circuit) generally has electronic circuit elements such as transistors, diodes and resistors fabricated integrally on a single body of semiconductor material. The various circuit elements are connected through conductive connectors to form a complete circuit which can contain millions of individual circuit elements. Typically, interconnect lines form horizontal connections between electronic circuit elements while conductive via plugs form vertical connections between the electronic circuit elements, resulting in layered connections. Interconnects provide the electrical connections between the various electronic elements of an IC and they form the connections between these elements and the device's external contact elements, such as pins, for connecting the IC to other circuits. Interconnects for connecting IC circuits to external contact elements typically include bond pads. These electrically conductive pads are fabricated in the IC to connect the IC circuit elements and interconnects to external circuits. Each chip typically includes many bond pads. Packaging techniques and materials are utilized to protect individual wafer chips, also known as dice, and to connect the bond pads to external circuits such as printed circuit boards or electronic products. IC chips typically have a top layer, known as a passivation layer, to protect the underlying chip structure from the potentially harmful effects of environmental contaminants, including moisture, light, radiation, heat and mechanical stress. Techniques for forming a permanent, electrically conductive, bond between the pad and external circuits include solder bump bonding and wire bonding.

An example of a conventional solder bump bonding technique employing a bond pad is schematically illustrated in FIG. 1. A bond pad 110 is formed in a dielectric layer 112 which is formed on dielectric layer 114. A passivation layer 116 that is formed on the dielectric layer 112 and the pad 110 includes a passivation opening 118 exposing a portion 120 of the top surface of the pad. Alternatively, the opening such as opening 118 can extend across the entire top surface of the pad (not shown). An electrically conductive UBM (under bump metallization) layer 124 is formed on portion 120 of the pad and inside opening 118, such that UBM layer 124 extends partly on passivation layer 116. Finally, a solder bump 126 is formed on UBM 124. Solder bumps generally contain Pb/Sn alloys having a low melting point. Typical conductive materials for bond pads, such as pad 110, include aluminum, copper and various metal alloys. The UBM is generally employed to provide a bond between the pad and the bump such that the bond has improved mechanical strength and/or improved electrical conductivity between the bump and the pad. The UBM includes single layer or multilayer constructions of metals and/or metal alloys. The passivation layer generally includes silicon oxide, silicon nitride or dielectric polymers such as polyimide. Pad 110 is connected to elements of an IC structure 130, through interconnect lines such as line 128 upon which the pad is fabricated. Interconnect line 128 can for example be fabricated in a dielectric layer 114 underlying layer 112. Typically, the interconnect line for the pad is fabricated in a metal layer which is separated from an underlying IC metal layer by a via layer. The via plugs provide the connection between the interconnect lines in these metal layers. Optionally, a repassivation layer (not shown) can be deposited on passivation layer 116, in which case the UBM can extend through the passivation and repassivation layers, in order to provide a stress buffer for the chip. It is also known to form a solder bump on a bond pad without the use of a UBM (not shown).

A chip having solder bumps such as bump 126 (FIG. 1) can be bonded to an external circuit using for example a conventional technique known as FC (flip chip) bonding, as is schematically illustrated in FIG. 2. The solder bump 210, similar to bump 126 shown in FIG. 1, is fabricated on bond pad 212, depicted in FIG. 2, using a conventional technique for example as described in connection with FIG. 1. Returning to FIG. 2, a solder flux (not shown) is applied to the surface of bump 210. The chip is flipped over and soldered on an external contact 214 of a device, such as a printed circuit board 216. An underfill material, for example epoxy, 218 is then applied to the structure to fill the gaps between the chip and the external device. The techniques that are associated with the bonding of a chip or an IC structure on an external circuit are usually referred to as packaging or assembly.

Conventional wire bonding includes bonding an aluminum wire to an aluminum bond pad, as schematically illustrated in FIG. 3. An Al bond pad 310 is formed in a dielectric layer 312 which is formed on dielectric layer 314, which for example includes an interconnect line 316 upon which pad 310 is fabricated. Interconnect line 316 connects bond pad 310 to an IC structure 318. An aluminum bond wire 320 is positioned in contact with pad 310. A bond 322 is then formed between wire 320 and pad 310, through the transmission of a pulse of ultrasonic energy between wire 320 and pad 310. This bonding process is typically assisted by forcing the wire onto the pad during the ultrasonic energy transmission. Gold wire bonds (not shown) can be fabricated on an A1 bond pad such as shown in FIG. 3, wherein the pad can include a gold or silver plated surface. Gold wire bonding generally includes thermosonic, thermocompression or ultrasonic bonding techniques.

While Al and Al/Cu alloy bond pads are in widespread use, it is recognized that Cu is a preferred material for pads, because Cu has a higher electrical conductivity than Al. However, there are well known disadvantages that are associated with the use of Cu in IC structures. These disadvantages include a lower adhesion strength between Cu and adjacent dielectric layers, than is obtained between Al and adjacent dielectric materials. The disadvantages resulting from the use of Cu also include Cu diffusion into the surrounding dielectric material and the possible diffusion of contaminants, such as fluorine, from the dielectric material to the copper surface, possible causing IC electrical and/or structural malfunction or failure. It is important to achieve the highest possible bond strength possible between a bond pad and the adjacent dielectric layers since a pad is typically subjected to thermal and/or mechanical stress during the bump bonding or wire bonding process, such as for example the ultrasonic energy that is employed in some wire bonding techniques. The mechanical stress usually occurs in a direction that is approximately parallel to the pad layer and it can, for example, result in a complete or partial rupture of the bond between the pad and the passivation layer as well as the underlying IC structure.

It is known to fabricate bond pads on a layer of C-doped silicon oxide materials. These materials include C-doped silicon oxide materials, such as oxidized organo silane materials that are formed by partial oxidation of an organo silane compound, such that the dielectric material includes a carbon content of at least 1% by atomic weight, as described in U.S. Pat. Nos. 6,072,227 (Yau et al., 2000) and 6,054,379 (Yau et al., 2000) and U.S. patent application Ser. No.: 09/553,461 which was filed Apr. 19, 2000, a continuation-in-part of U.S. Pat. No.: 6,054,379. Commonly assigned U.S. Pat. Nos. 6,072,227 and 6,054,379, and U.S. patent application Ser. No. 09/553,461 are herein incorporated by reference in their entireties.

The oxidized organo silane materials, described in the '227 and '379 patents and the '461 patent application, are formed by incomplete or partial oxidation of organo silane compounds generally including the structure:

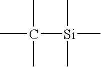

In this structure, —C—is included in an organo group and some C—Si bonds are not broken during oxidation. Preferably —C—is included in an alkyl, such as methyl or ethyl, or an aryl, such as phenyl. Suitable organo groups can also include alkenyl and cyclohexenyl groups and functional derivatives. Preferred organo silane compounds include the structure SiHₐ(CH₃)_{b}(C₂H₅)_{c}(C₆H₅)_{d}, where a=1 to 3, b=0 to 3, c=0 to 3, d=0 to 3, and a+b+c+d=4, or the structure Si₂Hₑ(Ch₃)_{f}(C₂H₅)_{g}, (C₆H₅), where e=1 to 5, f=0 to 5, g=0 to 5, h=0 to 5, and e+f+g+h=6.

Suitable organo groups include alkyl, alkenyl, cyclohexenyl, and aryl groups and functional derivatives. Examples of suitable organo silicon compounds include but are not limited to:

| | |
|---|---|
| methylsilane | CH₃—SiH₃ |
| dimethylsilane | (CH₃)₂—SiH₂ |
| trimethylsilane | (CH₃)₃—SiH |
| tetramethylsilane | (CH₃)₄—Si |
| dimethylsilanediol | (CH₃)₂—Si(OH)₂ |
| ethylsilane | CH₃—CH₂—SiH₃ |
| phenylsilane | C₆H₅—SiH₃ |
| diphenylsilane | (C₆H₅)₂—SiH₂ |
| diphenylsilanediol | (C₆H₅)₂—Si—(OH)₂ |
| methylphenylsilane | C₆H₅—SiH₂—CH₃ |
| disilanomethane | SiH₃—CH₂—SiH₃ |
| bis(methylsilano)methane | CH₃—SiH₂—CH₂—SiH₂—CH₃ |
| 1,2-disilanoethane | SiH₃—CH₂—CH₂—SiH₃ |
| 1,2-bis(methylsilano)ethane | CH₃—SiH₂—CH₂—CH₂—SiH₂—CH₃ |
| 2,2-disilanopropane | SiH₃—C(CH₃)₂—SiH₃ |
| 1,3,5-trisilano-2,4,6-trimethylene | —(—SiH₂CH₂—)₃— (cyclic) |
| dimethyldimethoxysilane | (CH₃)₂—Si—(OCH₃)₂ |
| diethyldiethoxysilane | (CH₃CH₂)₂—Si—(OCH₂CH₃)₂ |
| dimethyldiethoxysilane | (CH₃)₂—Si—(OCH₂CH₃)₂ |
| diethyldimethoxysilane | (CH₃CH₂)₂—Si—(OCH₂CH₃)₂ |
| 1,3-dimethyldisiloxane | CH₃—SiH₂—O—SiH₂—CH₃ |
| 1,1,3,3-tetramethyldisiloxane | (CH₃)₂—SiH—O—SiH—(CH₃)₂ |
| hexamethyldisiloxane | (CH₃)₃—Si—O—Si—(CH₃)₃ |
| 1,3-bis(silanomethylene)disiloxane | (SiH₃—CH₂—SiH₂—)₂—O |
| bis(1-methyldisiloxanyl)methane | (SiH₃—SiH₂—O—SiH₂—)₂—CH₂ |
| 2,2-bis(1-methyldisiloxanyl)propane | (CH₃—SiH₂—O—SiH₂—)₂—O(CH₃)₂ |
| 2,4,6,8-tetramethylcyclotetrasiloxane | —(—SiHCH₃—O—)₄— (cyclic) |
| octamethylcyclotetrasiloxane | —(—Si(CH₃)₂—O—)₄— (cyclic |
| 2,4,6,8,10-pentamethylcyclopentasiloxane | —(—SiHCH₃—O—)₅— (cyclic) |
| 1,3,5,7-tetrasilano-2,6-dioxy-4,8-dimethylene | —(SiH₂—CH₂—SiH₂—O—)₂— (cyclic) |
| 2,4,6-trisilanetetrahydropyran | —SiH₂—CH₂—SiH₂—CH₂—SiH₂—O— (cyclic) |
| 2,5-disilanetetrahydrofuran | —SiH₂—CH₂—CH₂—SiH₂—O— (cyclic) |
| and fluorinated derivatives thereof. | |

Preferred organo silane compounds include but are not limited to: methylsilane; dimethylsilane; trimethylsilane; tetramethylsilane; dimethylsilanediol; diphenylsilane; diphenylsilanediol; methylphenylsilane; bis(methylsilano)methane; 1,2-bis(methylsilano)ethane; 1,3,5-trisilano-2,4,6-trimethylene; dimethyldimethoxysilane; diethyldiethoxysilane; dimethyldiethoxysilane; diethyldimethoxysilane; hexamethyldisiloxane; octamethylcyclotetrasiloxane; and fluorinated derivatives thereof. The most preferred organo silane compounds include methyl silane and trimethyl silane.

The organo silane compounds are oxidized during deposition by reaction with oxygen (O₂) or oxygen containing compounds such as nitrous oxide (N₂O) and hydrogen peroxide (H₂O₂), such that the carbon content of the deposited film is from 1% to 50% by atomic weight, preferably about 20%. The oxidized organo silane layer has a dielectric constant of about 3.0. Carbon, including some organo functional groups, remaining in the oxidized organo layer contributes to low dielectric constants and good barrier properties providing a barrier that inhibits for example diffusion of moisture or metallic components. These oxidized organo silane materials exhibit good adhesion properties to silicon oxide and silicate glass as well as typical dielectric materials employed in IC structures. The above described oxidized organo silanes include BLACK DIAMOND™ technology, available from Applied Materials, Inc. located in Santa Clara, Calif.

Plasma conditions for depositing a layer of the oxidized organo silane material having a carbon content of at least 1% by atomic weight, include a high frequency RF power density from about at least 0.16 W/cm² and a sufficient amount of organo silane compound with respect to the oxidizing gas to provide a layer with carbon content of at least 1% by atomic weight. When oxidizing organo silane materials with N₂O, a preferred high frequency RF power density ranges from about 0.16 W/cm² to about 0.48 W/cm². These conditions are particularly suitable for oxidizing CH₃—SiH₃ with N₂O. Oxidation of organo silane materials such as (CH₃)₃—SiH with O₂ is preferably performed at a high frequency RF power density of at least 0.3 W/cm², preferably ranging from about 0.9 W/cm² to about 3.2 W/cm². Suitable reactors for depositing this material include parallel plate reactors such as those described in the '379 and '227 patents.

A variety of techniques are employed to create interconnect lines and via plugs. One such technique involves a process generally referred to as dual damascene, which includes forming a trench and an underlying via hole. The trench and the via hole are simultaneously filled with a conductor material, for example a metal, thus simultaneously forming an interconnect line and an underlying via plug.

In view of the electrical conductivity advantage of Cu compared with Al or Al/Cu alloys, the need exists for improved techniques to reduce or eliminate where possible the disadvantages that are associated with the use of Cu as a material for IC bond pads.

### SUMMARY OF THE INVENTION

Embodiments of the present invention provide novel techniques, methods and structures to obtain improvements in Cu bond pad technology.

In one embodiment of the present invention a Cu bond pad having a contiguous interconnect line is formed. A passivation layer is deposited on the Cu bond pad. A passivation hole is formed in the passivation layer, wherein the hole exposes at least a portion of the bond pad.

In another embodiment of the present invention a duplex bond pad is formed. The duplex bond pad includes a Cu bond pad having a contiguous interconnect line. A passivation layer is deposited on the Cu bond pad. A passivation hole is formed through the passivation layer exposing at least a portion of the Cu bond pad. The duplex bond pad further includes an Al plug that is deposited in the passivation hole, and an Al bond pad that is formed on the Al plug and on the passivation layer.

In yet another embodiment of the present invention a duplex bond pad is formed. The duplex bond pad includes a Cu bond pad having a contiguous interconnect line. A passivation layer is deposited on the Cu bond pad. Via holes are formed through the passivation layer such that each via hole exposes at least a portion of the Cu bond pad. The duplex bond pad further includes Al plugs that are deposited in the via holes, and an Al bond pad that is formed on the Al via plugs and on the passivation layer.

In a further embodiment of the present invention a bond pad hole having a contiguous trench is etched in a dielectric layer. A barrier/seed layer is formed in the pad hole and trench. A Cu layer is then formed in the lined pad hole and the lined trench, such that the Cu layer provides an underfill of the pad hole and trench. A metal overcoat layer is formed on the Cu layer, providing an overfill of the pad hole and the trench. The structure is planarized to define a bond pad having an overcoat layer which comprises at least 95% of the top surface of the bond pad, a barrier/seed liner and a contiguous interconnect line. The interconnect line is provided with an overcoat layer which comprises at least 95% of the top surface of the line. A passivation layer is deposited on the dielectric layer and on the bond pad including the contiguous interconnect line. A passivation hole is etched in the passivation layer such that the passivation hole exposes at least a portion of the overcoat layer of the bond pad.

In an additional embodiment of the present invention, first dielectric and second dielectric layers are sequentially deposited on an IC substrate. A pad hole and contiguous trench are etched in the second dielectric layer. A via hole is etched in the first dielectric layer, such that the via hole connects the trench with the IC substrate. A dual damascene technique is then employed to simultaneously fill the via hole, pad hole and trench with Cu. A Cu bond pad having a contiguous Cu interconnect line is subsequently defined in the second dielectric layer. A passivation layer is deposited on the second dielectric layer and on the bond pad having the contiguous interconnect line. A passivation hole is then etched in the passivation layer such that the passivation hole exposes at least a portion of the bond pad.

In yet another embodiment of the present invention, first dielectric and second dielectric layers are sequentially deposited on an IC substrate. A pad hole and contiguous trench are etched in the second dielectric layer. A via hole is etched in the first dielectric layer, such that the via hole connects the trench with the IC substrate. A substantially conformal barrier/seed liner is formed inside the via hole, pad hole and contiguous trench, thereby forming a lined via hole and a lined pad hole having a contiguous lined trench. A dual damascene technique is then employed to simultaneously form a Cu layer inside the lined via hole, inside the lined pad hole and inside the lined contiguous trench. The Cu layer is formed to provide an underfill of the pad hole and the trench. Subsequently, a substantially conformal metal overcoat layer is formed on the Cu layer such that the metal overcoat layer provides an overfill of the pad hole and the trench. A Cu bond pad having a barrier/seed layer, a metal overcoat layer which comprises at least 95% of the top surface of the bond pad and a contiguous Cu interconnect line is defined in the second dielectric layer. A passivation layer is provided on the second dielectric layer and on the bond pad having the contiguous interconnect line. A passivation hole is then etched in the passivation layer such that the passivation hole exposes at least a portion of the overcoat layer of the bond pad.

In a further embodiment of the present invention a bond pad hole having a contiguous trench is etched in a dielectric layer. A barrier/seed layer is formed in the pad hole and trench. A Cu layer is then formed in the lined pad hole and the lined trench, such that the Cu layer provides an overfill of the pad hole and trench. The structure is planarized to define a bond pad portion and a contiguous interconnect line portion. A metal overcoat layer is then formed on the Cu bond pad portion and the contiguous line portion, employing conventional electroless metal deposition techniques, thereby fabricating a bond pad and a contiguous line, such that the overcoat layer completely covers the Cu material of the top surface of the bond pad and the line interconnect line. A passivation layer is deposited on the dielectric layer and on the bond pad and contiguous interconnect line. A passivation hole is etched in the passivation layer such that the passivation hole exposes at least a portion of the metal overcoat layer of the bond pad.

In yet a further embodiment of the present invention a bond pad is formed in a dielectric layer such that the bond pad is exposed. A passivation layer is deposited on the bond pad and the dielectric layer. Via holes are etched in the passivation layer such that each of the via holes exposes at least a portion of the bond pad. A solder bump is then formed on the passivation layer and inside the via holes such that the solder bump material forms via plugs.

### BRIEF DESCRIPTION OF THE DRAWINGS

FIG. 1 is a schematic cross-sectional side view illustrating a prior art IC structure including a bond pad and a solder bump.

FIG. 2 is a schematic cross-sectional side view illustrating a prior art flip chip technique for bonding the IC structure illustrated in FIG. 1 to an external circuit.

FIG. 3 is a schematic cross-sectional side view illustrating a prior art technique for bonding a wire to a bond pad of an IC structure.

FIGS. 4A-4F are schematic cross-sectional perspective views illustrating an embodiment of the present invention for forming a bond pad at sequential stages.

FIG. 4G is a schematic cross-sectional side view of FIG. 4F along the lines X1-X1 of FIG. 4F.

FIGS. 5A-5C are schematic cross-sectional side views illustrating an embodiment of the present invention for forming solder bumps of the present invention at sequential stages.

FIGS. 6A-6D are schematic cross-sectional side views illustrating embodiments of the present invention for forming a wire bond pad and a solder bump at sequential stages.

FIGS. 7A and 7B are schematic cross-sectional side views illustrating an embodiment of the present invention for forming a solder bump at sequential stages.

FIGS. 8A-8C are schematic cross-sectional side views illustrating an embodiment of the present invention for forming a duplex bond pad including a wire bond pad at sequential stages.

FIGS. 9A and 9B are cross-sectional side views illustrating an embodiment of the present invention for forming a duplex bond pad including a wire bond pad at sequential stages.

FIGS. 10A-10G are schematic cross-sectional views illustrating an embodiment of the present invention for forming a wire bond pad at sequential stages, wherein FIGS. 10A-10E are perspective views while FIGS. 10F and 10G are side views.

FIGS. 11A and 11B are schematic cross-sectional side views illustrating an embodiment of the present invention for forming a bond pad at sequential stages

FIG. 12 is a schematic cross-sectional side view illustrating an embodiment of the present invention for forming a wire bond pad.

FIGS. 13A and 13B are schematic cross-sectional perspective views illustrating an embodiment of the present invention for forming a bond pad hole at sequential stages.

FIGS. 14A-14D are schematic cross-sectional perspective views illustrating an embodiment of the present invention for forming a bond pad at sequential stages.

FIG. 14E is a schematic cross-sectional side view of FIG. 14D along the lines X2-X2.

FIG. 14F is a schematic cross-sectional side view illustrating an embodiment of the present invention for forming a bond pad, after the fabrication of the embodiments shown in FIGS. 14A-14E.

FIG. 15 is a schematic cross-sectional side view illustrating an embodiment of the present invention for forming a UBM through a passivation layer deposited on a bond pad, sequentially to the embodiments shown in FIGS. 14A-14F

FIGS. 16A and 16B are cross-sectional side views illustrating an embodiment of the present invention for forming a duplex bond pad at sequential stages, sequentially to the embodiments shown in FIGS. 14A-14F.

FIGS. 17A-17D illustrate an embodiment of the present invention for forming a bond pad at sequential stages, wherein FIGS. 17A-17C are schematic cross-sectional perspective views while FIG. 17D shows a cross-sectional side view.

FIGS. 18A-18C are schematic views illustrating an embodiment of the present invention for forming a solder bump at sequential stages, wherein FIGS. 18A and 18C are cross-sectional side views while FIG. 18B is a plan view.

FIG. 19 is a schematic cross-sectional view for forming a solder bump of the present invention.

FIGS. 20A and 20B are schematic cross-sectional perspective views illustrating an embodiment of the present invention for forming a bond pad at sequential stages.

FIG. 20C is a schematic cross-sectional side view of FIG. 20B along the lines X3-X3.

FIG. 20D is a schematic cross-sectional side view illustrating an embodiment of the present invention for forming a duplex bond pad sequentially to the embodiment shown in FIGS. 20A-20C.

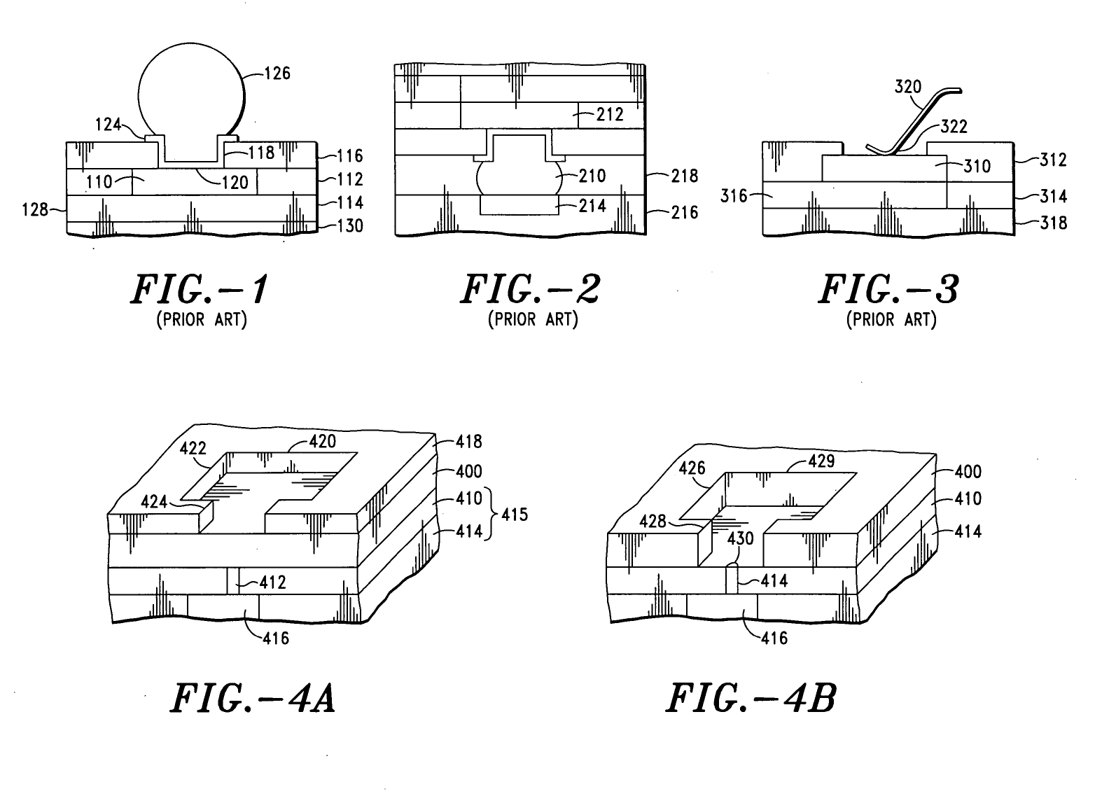

### DETAILED DESCRIPTION OF THE INVENTION

While describing the invention and its embodiments, certain terminology will be utilized for the sake of clarity. It is intended that such terminology includes the recited embodiments as well as all equivalents.

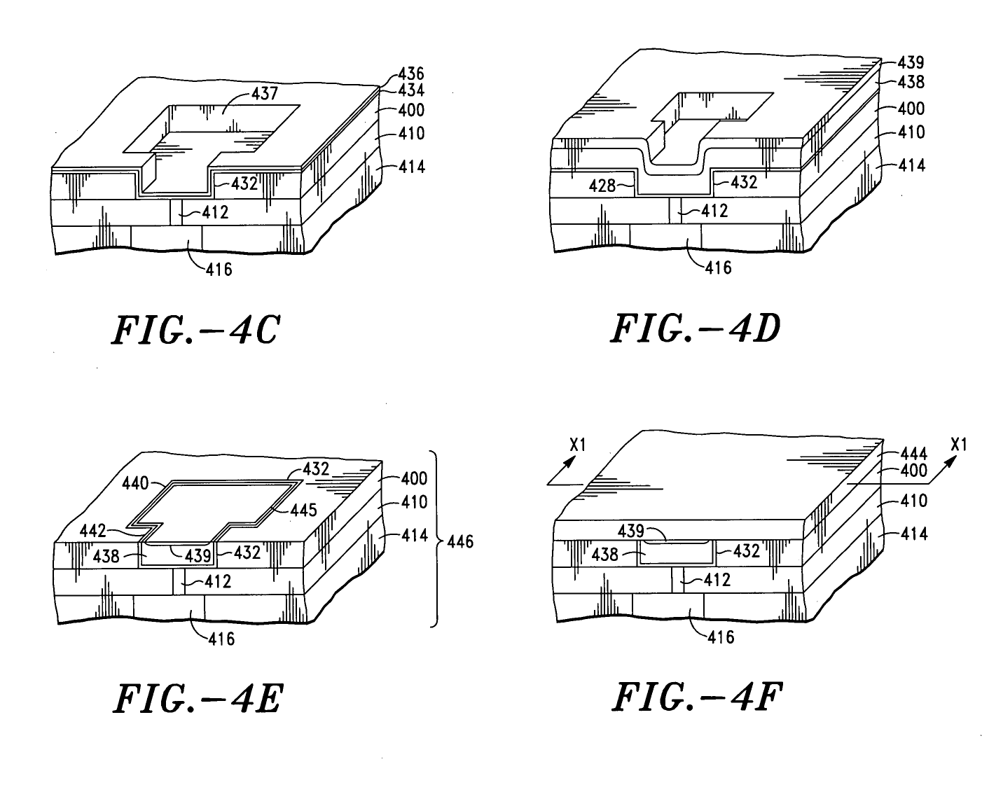

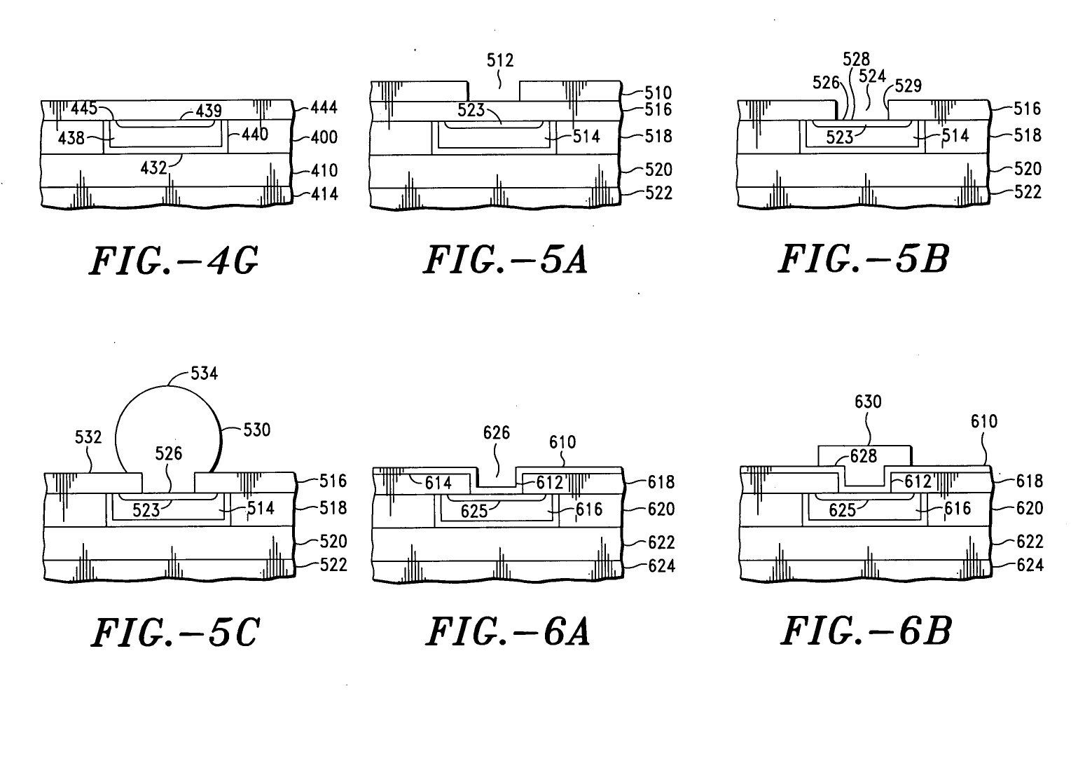

One embodiment of the invention, schematically illustrated in FIGS. 4A-4G, shows a processing sequence for forming a bond pad. As depicted in FIG. 4A, a dielectric layer 400 is deposited on a dielectric layer 410 including one or more via plugs 412. Dielectric layer 410 is deposited on a substrate, such as an IC structure, 414 including an electrically conductive element 416 underlying via plug 412, such that via plug 412 provides an electrically conductive contact with conductive element 416. Examples of conductive elements include conductive connectors and electronic circuit elements. The expression “IC structure” as defined herein, includes completely formed integrated circuits and partially formed integrated circuits. Layer 410 can be referred to as the top layer of an IC structure 415 including layer 410 and IC structure 414.

A photoresist layer 418 having an etch mask or pattern 420 is formed on dielectric layer 400, see FIG. 4A. Mask 420 includes a mask section 422 for etching a bond pad hole and a contiguous mask section 424 that is provided as the pattern for etching a trench. Trench mask section 424 overlays via plug 412. As illustrated in FIG. 4B and using conventional techniques, mask 420 is employed for etching layer 400 in order to form pad hole 426 and trench 428 such that hole 426 and trench 428 form a contiguous opening 429 in layer 400. Opening 429 extends through layer 400, exposing underlying layer 410. Top surface 430 of via plug 412 is exposed in trench 428. Photoresist layer 418 is then removed, resulting in the structure that is schematically illustrated in FIG. 4B.

An electrically conductive, substantially conformal barrier/seed sandwich layer 432, see FIG. 4C, is formed in the pad hole and the trench and on dielectric layer 400, thereby forming a liner comprising a layer covering the bottom and side surfaces of the pad hole and the trench and additionally covering the surface of via plug 412. Barrier/seed sandwich layer 432 is fabricated as follows. An electrically conductive, substantially conformal Cu diffusion barrier layer 434 is deposited in the pad hole, in the trench and on the exposed top surface of dielectric layer 400, as shown in FIGS. 4C and 4D. Typical Cu diffusion barrier materials include refractory metals such as Ta, Ti, TiW and compounds of refractory metals such as TiN, TiC, TaN and TaC, as well as combinations of these materials such as TaN/Ta and Ti/TaN/Ta. Subsequently, a substantially conformal electrically conductive Cu seed layer 436 is deposited on barrier layer 434. Suitable seed layer materials include Cu and Cu alloys with a low percentage of one or more other metals. The techniques for depositing a substantially conformal barrier/seed sandwich layer, such as layer 432 are well known to those of ordinary skill in the art. The electrically conductive barrier/seed sandwich layer provides a Cu diffusion barrier as well as a Cu seed layer for subsequently depositing a Cu layer thereon. It is noted that conformal sandwich layer 432 forms a cavity 437 conforming to pad hole 426 and trench 428, shown in FIG. 4B.

The fabrication process is continued by deposition of a substantially conformal Cu layer 438 on sandwich layer 432 including inside the barrier/seed lined pad hole and trench, as depicted in FIG. 4D. Cu layer 438 is deposited employing conventional techniques, using for example electroplating techniques, such that it results in an underfill of the pad hole and the contiguous trench. In a next processing step, a substantially conformal metal overcoat layer 439 is deposited on Cu layer 438, see FIG. 4D. The thickness of layer 439 is such that it results in an overfill of the pad hole and the contiguous trench. Subsequently, conventional CMP (chemical mechanical polishing) is used to remove excess overcoat layer as well as excess Cu layer and barrier/seed sandwich layer materials from the top surface of dielectric layer 400, see FIG. 4E, to define a novel bond pad 440 and a contiguous interconnect line 442, wherein the pad and line include barrier/seed sandwich layer 432 and metal overcoat layer 439. As illustrated in FIG. 4E, overcoat layer 439 does not completely cover Cu layer 438. A very narrow section 445 of the top surface of Cu layer 438 is not covered by layer 439. Section 445 of Cu layer 438 comprises Cu metal that is positioned between barrier/seed layer 432 and metal overcoat layer 439, however overcoat layer 439 comprises at least 95% of the top surface of bond pad 440 and at least 95% of the top surface of contiguous interconnect line 442. It is noted that structure 446 shown in FIG. 4E illustrates a novel IC structure comprising a bond pad of the present invention.

As shown in FIG. 4F, a passivation layer 444 is deposited on dielectric layer 400 and on the novel pad and interconnect line. A schematic cross-sectional view of the structure depicted in FIG. 4F along the lines X1-X1 is shown in FIG. 4G. With reference to FIG. 4G it is noted that the cross-sectional view of the structure includes a cross-sectional view of bond pad 440. The pad is coated with a metal overcoat layer 439. A typical thickness of overcoat layer 439 of the bond pad and the interconnect line ranges from about 0.001 micron to about 5.0 micron. The bottom and side surfaces of the bond pad and contiguous line are provided with a sandwich layer 432 of barrier/seed material. As noted in connection with FIG. 4E, overcoat layer 439 does not cover the entire top surface of Cu layer 438.

FIGS. 5A-5C illustrate another embodiment of the present invention, wherein a solder bump is fabricated on a novel bond pad such as novel bond pad 440, depicted in FIG. 4G. FIG. 5A shows a structure wherein a photoresist layer 510 having a hole pattern 512 is formed on a structure that is similar to the structure shown in FIG. 4G, i.e. components 514, 516, 518, 520, 522 and 523 depicted in FIG. 5A are similar to components 440, 444, 400, 410, 414 and 439 respectively shown in FIG. 4G. Pattern 512 overlaying novel bond pad 514, is then etched through passivation layer 516, thereby forming passivation hole 524, as depicted in FIG. 5B, and exposing a section 526 of top surface 528 of overcoat layer 523 of pad 514. Photoresist layer 510 is then removed, see FIG. 5B. The etching procedure illustrated in FIG. 5B results in passivation hole 524 including section 526 of pad 514 and sidewall 529 in passivation layer 516. Preferably sidewall 529 comprises an approximately cylindrical shape. Passivation hole 524 is formed such that passivation layer 516 extends on one or more portions of overcoat layer 523.

The structure shown in FIG. 5B can then be employed to form a solder bump 530, as illustrated in FIG. 5C. Solder bump 530 is formed on section 526 of pad 514 in passivation hole 524, i.e. the solder bump is fabricated on overcoat layer 523 of bond pad 514. Solder bump 530 can for example partly extend on top surface 532 of passivation layer 516. Top portion 534 of solder bump 530 typically extends about 10 micron to about 500 micron above top surface 532 of passivation layer 516. In connection with the embodiment shown in FIG. 5C, it is also contemplated to provide a coating of non-oxidizing material, such as Au, on the overcoat layer prior to fabricating the solder bump.

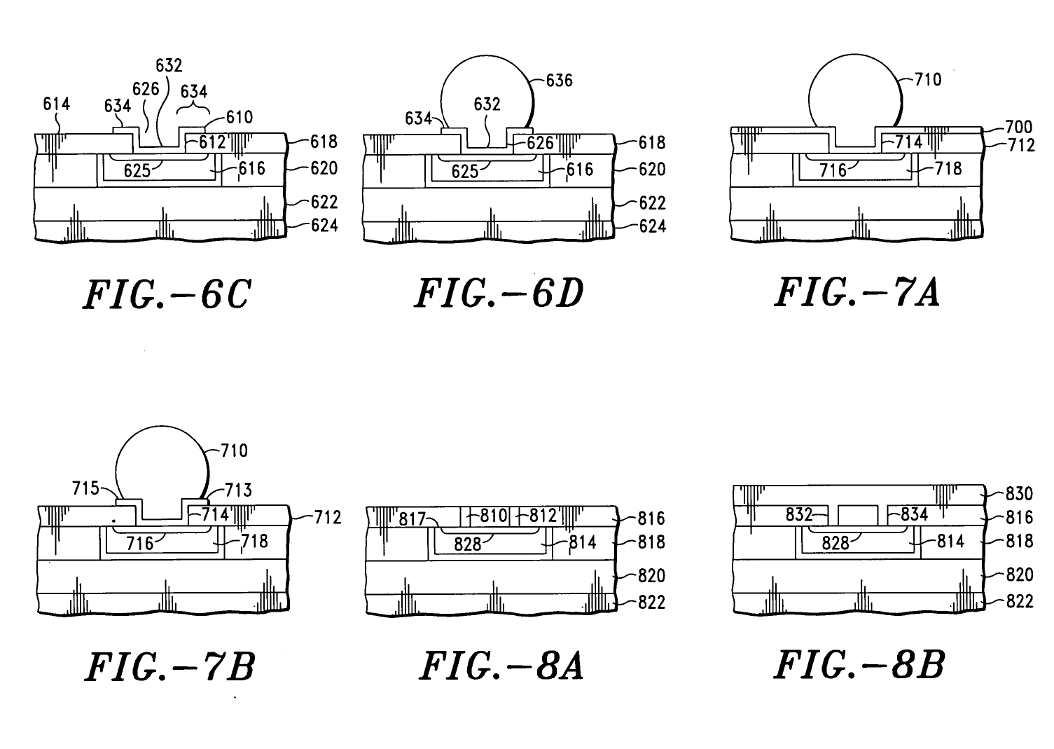

FIGS. 6A-6D illustrate another embodiment of the present invention for fabricating a solder bump on a novel bond pad such as novel bond pad 440 depicted in FIG. 4G. FIG. 6A illustrates a structure such as the structure shown in FIG. 5B, in addition including a UBM layer 610. Components 612, 616, 618, 620, 622, 624 and 625 shown in FIG. 6A are similar to components 524, 514, 516, 518, 520, 522 and 523 respectively, depicted in FIG. 5B. Layer 610 (FIG. 6A) is deposited on exposed top surface 614 of passivation layer 618 and inside passivation hole 612, i.e. UBM layer 610 is deposited on overcoat layer 625 of novel pad 616. Preferably UBM layer 610 comprises a conformal layer, such that a UBM hole 626 is formed. As illustrated in FIG. 6B, a subtractive etch mask 630 is fabricated on the structure shown in FIG. 6A, such that the mask protects hole 626 as well as a portion 628 (FIG. 6B) of layer 610 that is adjacent to hole 626. A conventional subtractive etch procedure is then employed to remove layer 610 from the surface of passivation layer 618 where layer 610 is not protected by mask 630. Thereafter, mask 630 is removed resulting in UBM 632 illustrated in FIG. 6C. A portion 634 of UBM 632 is retained on top surface 614 of passivation layer 618. As shown in FIG. 6D and employing conventional techniques, solder bump 636 is fabricated inside UBM 632 that is formed in hole 626, and on ring shaped UBM portion 634, covering all or part of UBM portion 634. Typically, portion 634 of UBM 632 is ring shaped, but other shapes of portion 634 are also operable with regard to embodiments of the present invention.

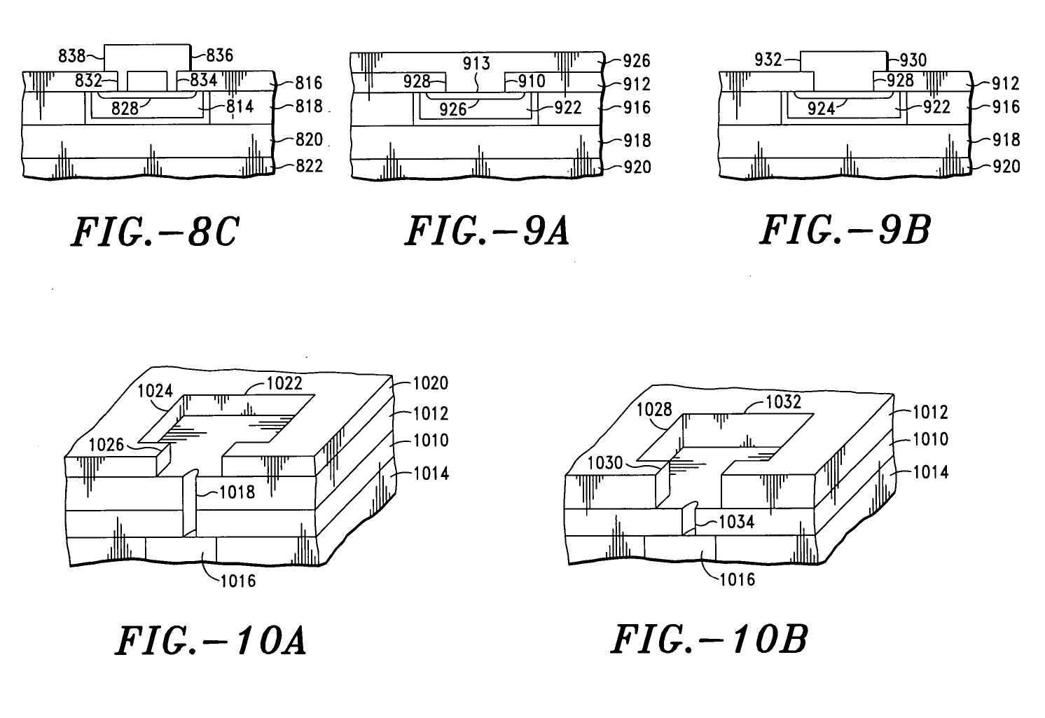

In an alternative embodiment of the invention illustrated in FIGS. 6A-6D, a subtractive etch is utilized wherein the solder bump provides a subtractive etch mask for forming the UBM, as shown in FIGS. 7A and 7B. With reference to FIG. 7A a structure similar to the structure illustrated in FIG. 6A includes a UBM layer 700 which is similar to UBM layer 610 depicted in FIG. 6A. A solder bump 710 (FIG. 7A) is formed on UBM layer 700 for example using a process similar to the fabrication of solder bump 636 on UBM 632 shown in FIG. 6D. Returning to FIG. 7A, UBM layer 700 is fabricated on passivation layer 712 and inside passivation hole 714, such that the UBM is formed on overcoat layer 716 of novel bond pad 718. Bond pad 718 is similar to bond pad 616 (FIG. 6A). An etch back process is then used for etching the exposed portions of layer 700, such that solder bump 710 provides the subtractive etch mask, see FIG. 7B. This subtractive etch process results in solder bump 710, having a UBM 713 including an approximately ring or collar shaped portion 715 that is retained on passivation layer 712 due to the etch masking effect of solder bump 710.

It is noted that techniques for fabricating solder bumps on an electrically conductive surface, such as bumps 530 (FIG. 5C), 636 (FIG. 6D) and 710 (FIG. 7B) are well known to those of ordinary skill in the art. These techniques are suitable for fabricating solder bumps on the novel bond pads of the present invention such as pads 514 (FIG. 5C), 616 (FIG. 6D) and 718 (FIG. 7B).

While UBM 632 (FIG. 6C) and UBM 712 (FIG. 7B) are exemplified as single layer UBM structures such as a Ni, it is also contemplated to use multi layer UBM structures. Typical multi layer UBM layers include for example Al/NiV/Cu, Ti/NiV/Cu and TiW/Ni/Cu.

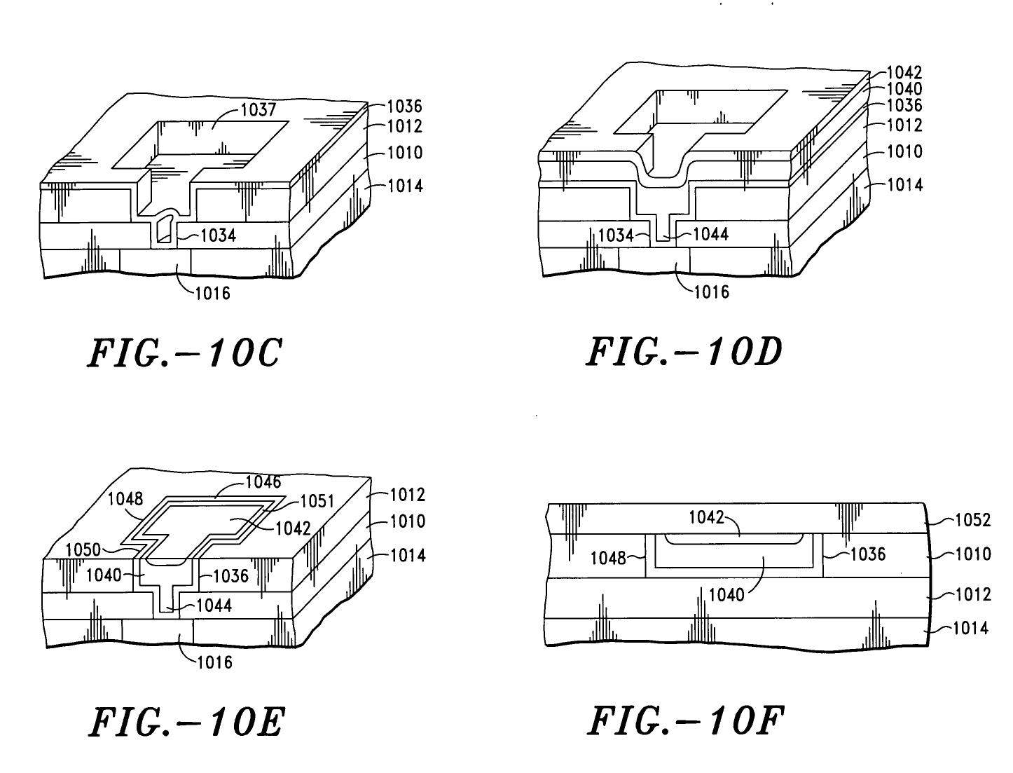

FIGS. 8A-8C illustrate another embodiment of the present invention, wherein a novel duplex bond pad is fabricated for wire bonding of an external circuit to an IC structure. The expression “duplex bond pad” as defined herein, includes structures wherein an upper bond pad that is adapted for wire bonding, is connected through a dielectric layer to a lower bond pad. As shown in FIG. 8A, one or more via holes, such as via holes 810 and 812 are etched through a passivation layer 816 to metal overcoat layer 828 of a novel Cu containing bond pad 814. Components 814, 818, 820, 822 and 828 shown in FIG. 8A are similar to components 440, 400, 410, 414, and 439 respectively depicted in FIG. 4G. Passivation layer 816 (FIG. 8A) has a similar composition as passivation layer 444 (FIG. 4G). As shown in FIG. 8B, an Al layer 830 is then deposited on passivation layer 816 and inside via holes 810 and 812, thereby forming Al via plugs 832 and 834 respectively. Subsequently, a conventional subtractive Al etch is employed to form Al wire bond pad 836 on passivation layer 816, as shown in FIG. 8C. The structure including novel Cu containing pad 814, via plugs 832 and 834, and Al bond pad 836 comprises a novel duplex bond pad 838 having novel Cu containing primary bond pad 814 and Al secondary bond pad 836, see FIG. 8C. One or more Al or Au wires (not shown) that are connected to an external circuit, can be bonded to Al bond pad 836 of duplex bond pad 838 using for example conventional bonding techniques.

FIGS. 9A and 9B illustrate yet another embodiment of the present invention, for fabricating a novel duplex bond pad. As shown in FIG. 9A, a passivation hole 910 is formed in a passivation layer 912 such that the hole exposes at least a section 913 of overcoat layer 924 of a novel Cu containing pad 922, using techniques and materials similar to those that are used for fabricating the structure illustrated in FIG. 5B. It is noted that components 910, 912, 916, 918, 920, 922 and 924 shown in FIG. 9A are similar to components 524, 516, 518, 520, 522, 514 and 523 respectively depicted in FIG. 5B. Returning to FIG. 9A, an Al layer 926 is deposited on passivation layer 912 and inside passivation hole 910, such that an Al plug 928 that is formed in hole 910 contacts the underlying overcoat layer 924 of Cu containing pad 922. A conventional subtractive etch procedure is employed to form Al bond pad 930, see FIG. 9B. The structure including novel Cu containing pad 922, Al plug 928 and Al bond pad 930 comprises a novel duplex bond pad 932 having a Cu containing primary pad 922 and an Al secondary pad 930.

Structures such as those illustrated in FIGS. 4D-4G, 5A-5C, 6A-6D, 7B, 8A-8C, 9A and 9B include a metal overcoat layer. Examples of suitable metal overcoat layers for bond pads of the present invention include metal layers that are deposited utilizing conventional electroless techniques and conventional electroplating techniques. Suitable metals for overcoat layers of the novel bond pads include Ni, Co, Pd, Zn and Sn.

In additional embodiments of the present invention a novel bond pad, a contiguous interconnect line and one or more underlying via plugs are fabricated using novel dual damascene techniques as schematically illustrated in FIGS. 10A-10F. FIG. 10A depicts an embodiment of the present invention including dielectric layers 1010 and 1012 that are sequentially deposited on a IC substrate 1014, wherein the substrate includes an electrically conductive element 1016. Examples of conductive elements include conductive connectors and electronic circuit elements. Employing conventional etch techniques, a via pattern is etched through layers 1012 and 1010 thereby forming a hole 1018 extending through layers 1012 and 1010. Hole 1018 exposes a portion of the top surface of conductive element 1016. Subsequently, a photoresist layer 1020 having an etch mask or pattern 1022 is formed on dielectric layer 1012, see FIG. 10A. Mask 1022 includes a mask section 1024 for etching a bond pad hole and a mask section 1026 that is provided as the pattern for etching a trench. Trench mask section 1026 is open to underlying hole 1018. Then, as illustrated in FIG. 10B, mask 1022 is employed for etching layer 1012 in order to fabricate a bond pad hole 1028 and a trench 1030 such that pad hole 1028 and trench 1030 form a contiguous opening 1032 in layer 1012. Opening 1032 extends through layer 1012, exposing underlying layer 1010. This etching procedure retains the portion of hole 1018 that is fabricated in layer 1010, thereby forming via hole 1034 which connects trench 1030 to conductive element 1016. It is noted that the structure depicted in FIG. 10B includes a novel structure comprising a pad hole 1028, a contiguous interconnect line trench 1030 and a via hole 1034, wherein the structure is adapted for fabricating a dual damascene structure.

A substantially conformal electrically conductive barrier/seed sandwich layer 1036, see FIGS. 10C and 10D, is deposited in opening 1032, in via hole 1034, and on dielectric layer 1012 thus forming a barrier/seed sandwich liner on the bottom and sidewalls of the pad hole, trench and via hole, including the bottom of via 1034, thereby covering the exposed portion of conductive element 1016. As shown in FIG. 10C, barrier/seed layer 1036 forms a cavity 1037 conforming to the pad hole and the trench. It is noted that the materials of layers 1010 and 1012 shown in FIG. 10A are similar to the materials of layers 410 and 400 respectively depicted in FIG. 4A, while the components of substrate 1014 shown in FIG. 10A are similar to the components of substrate 414 depicted in FIG. 4A. Barrier/seed sandwich layer 1036 (FIGS. 10C and 10D) includes similar layers and materials as barrier/seed layer 432 (FIG. 4C).

As illustrated in FIG. 10D and using a dual damascene technique, the barrier/seed lined pad hole, trench and underlying via hole are then simultaneously filled with a substantially conformal Cu layer 1040, extending on layer 1036 that is formed on the top surface of dielectric layer 1012. Cu layer 1040 is deposited, using for example conventional electroplating techniques, such that it results in an underfill of the pad hole and contiguous trench, while completely filling barrier/seed line via hole 1034, thereby forming via plug 1044. In a next processing step, a substantially conformal metal overcoat layer 1042 is deposited on Cu layer 1042, see FIG. 10D. The thickness of overcoat layer 1042 is such that it results in an overfill of the pad hole and the contiguous trench. It is noted that layers 1036, 1040 and 1042 shown in FIG. 10D are similar to layers 432, 438 and 439 respectively depicted in FIG. 4D. Subsequently, employing conventional CMP techniques, excess barrier/seed layer 1036, Cu layer 1040 and overcoat layer 1042 materials are removed from the top surface dielectric layer 1012, see FIG. 10E. The foregoing process results in a novel dual damascene structure 1046 including a simultaneously deposited novel bond pad 1048, contiguous interconnect line 1050 and via plug 1044 as shown in FIG. 10E. With reference to FIG. 10E it is noted that a section 1051 of Cu layer 1040 comprises Cu metal that is positioned between barrier/seed layer 1036 and metal overcoat layer 1042. Section 1051 of the top surface of bond pad 1048 and line 1040 is similar to section 445 as described and illustrated in connection with FIG. 4E. Overcoat layer 1042 comprises at least 95% of the top surface of pad 1048 and at least 95% of the top surface of contiguous interconnect line 1050.

Employing techniques and materials similar to techniques and materials that are described in connection with FIGS. 4F and 4G, a passivation layer 1052, similar to passivation layer 444 shown in FIGS. 4F and 4G, is then deposited on the structure shown in FIG. 10E, resulting in the structure depicted in FIG. 10F which shows a cross-sectional view of novel bond pad 1048. As depicted in FIG. 10G, a passivation hole 1054 is formed in passivation layer 1052, similar to hole 524 (FIG. 5B). It is noted that structure 1056 illustrated in FIG. 10G shows an IC structure of the present invention including a novel bond pad 1048. Hole 1054 can then be utilized to fabricate a solder bump such as solder bump 530 (FIG. 5C), or to fabricate an Al wire bond pad such as wire bond pad 930 (FIG. 9B) or to fabricate a UBM such as UBM 632 (FIG. 6C) or UBM 712 (FIG. 7B). For example, as illustrated in FIG. 11A, UBM 1110 is fabricated according to these techniques in hole 1112 of passivation layer 1114, see FIG. 11A, wherein components 1112, 1114, 1116, 1118, 1120, 1122, 1124, 1126 and 1128 shown in FIG. 11A are similar to components 1054, 1052, 1010, 1012, 1014, 1048, 1042, 1040 and 1036 respectively illustrated in FIG. 10G. As shown in FIG. 11B a solder bump, such as solder bump 1130 can be fabricated on UBM 1110.

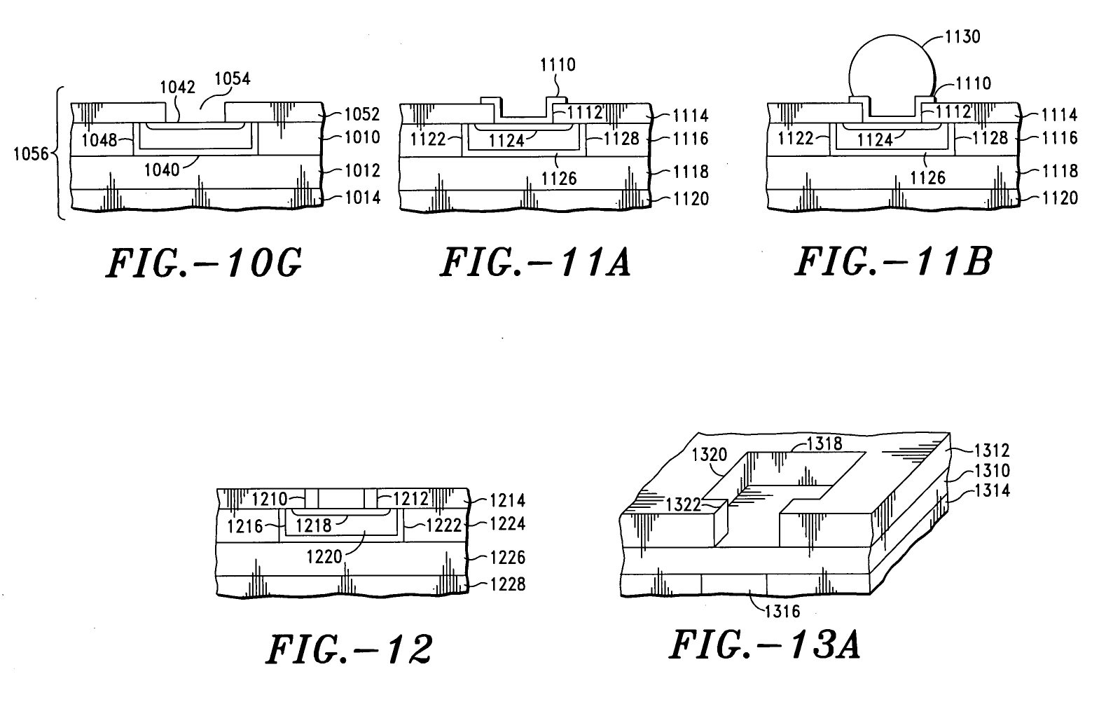

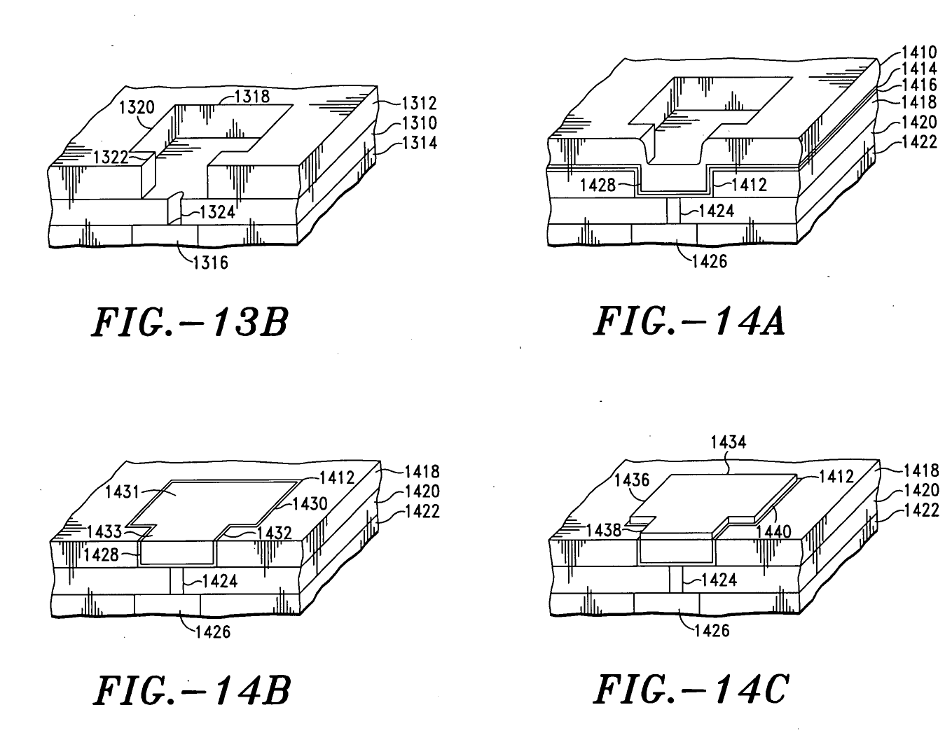

In another embodiment of the present invention illustrated in FIG. 12, via holes can be fabricated in a passivation layer of a structure such as the structure depicted in FIG. 10G, resulting in the structure shown in FIG. 12. With reference to FIG. 12, via holes 1210 and 1212 are formed in a passivation layer 1214 which is formed on a novel bond pad 1216. The via holes expose metal overcoat layer 1218 of the bond pad. Passiviation layer 1214 comprises similar materials as passivation layer 1052 (FIG. 10F). Components 1216, 1218, 1220, 1222, 1224, 1226 and 1228 shown in FIG. 12 are similar to components 1048, 1042, 1040, 1036, 1010, 1012 and 1014 depicted in FIG. 10F. Employing techniques similar to those described in connection with FIGS. 8B and 8C an Al wire bond pad similar to bond pad 836 (FIG. 8C) can be fabricated using the structure shown in FIG. 12.

An additional embodiment of the present invention is illustrated in FIGS. 13A and 13B. As shown in FIG. 13A, dielectric layers 1310 and 1312 that are sequentially deposited on a substrate, such as an IC structure, 1314 wherein the structure includes an electrically conductive element 1316. Examples of conductive elements include conductive connectors and electronic circuit elements. Employing a photoresist layer and an etch pattern, such as photoresist layer 418 and pattern 420 respectively shown in FIG. 4A, an opening 1318 is formed in dielectric layer 1312, see FIG. 13A. Opening 1318 extending through layer 1312, includes a bond pad hole 1320 and a contiguous trench 1322 adapted for forming an interconnect line, such that trench 1322 overlays conductive element 1316. Subsequently, using conventional techniques, a via hole 1324 is formed in the bottom of the trench, extending to the top surface of conductive element 1316, see FIG. 13B. It is noted that layers 1310, 1312 and 1314 shown in the structure illustrated in FIG. 13A are similar to layers 1010, 1012 and 1014 respectively depicted in FIG. 10B. Furthermore, it is noted that opening 1318, bond pad hole 1320, contiguous trench 1322 and via hole 1324 shown in the structure illustrated in FIG. 13B are similar to opening 1032, bond pad hole 1028, contiguous trench 1030 and via hole 1034 respectively depicted in FIG. 10B. Methods and materials can then be employed to fabricate structures such as those illustrated in FIGS. 10C-10G, 11A, 11B and 12 in order to form novel solder bump bond pads and wire bond pads similar to those described in connection with FIGS. 10G, 11A, 11B and 12.

The embodiments illustrated and described in connection with FIGS. 4E-4G, 5A-5C, 6A-6D, 7A, 7B, 8A-8C, 9A, 9B, 10E-10G, 11A, 11B, and 12 depict novel Cu containing bond pad structures having an overcoat layer which does not cover the entire top surface of the Cu bond pad, and which does not cover the entire surface of the contiguous interconnect line. However, as illustrated and described in connection with the following embodiments of the invention shown in FIGS. 14A-17D, metal overcoat layers comprising electroless deposited metal can be provided such that the entire top surface of the Cu material of the bond pad and the contiguous interconnect line is coated with the overcoat layer.

FIG. 14A depicts a structure similar to the structure shown in FIG. 4C, but additionally including a substantially conformal Cu layer 1410 which is electroplated on an electrically conductive barrier/seed sandwich layer 1412. The conformal Cu layer is deposited in a cavity 1428 that is formed in layer 1412, similar to cavity 437 shown in FIG. 4C. Returning to FIG. 14A, the thickness of Cu layer 1410 is such that it forms an overfill of cavity 1428. Components 1412, 1414, 1416, 1418, 1420, 1422, 1424, 1426 and 1428 shown in FIG. 14A are similar to components 432, 436, 434, 400, 410, 414, 412, 416 and 437 respectively depicted in FIG. 4C. Subsequently, conventional CMP is used to remove excess Cu layer 1410 and excess sandwich layer 1412 from the surface of dielectric layer 1418, see FIG. 14B. The CMP procedure results in defining Cu bond pad portion 1430 (FIG. 14B) including Cu material 1431 and contiguous Cu line portion 1432 including Cu material 1433. Then, as illustrated in FIG. 14C, a metal overcoat layer 1434 is deposited on the Cu material of the Cu bond pad portion and the Cu line portion, employing an electroless metal deposition technique, thereby forming a novel bond pad 1436 and a contiguous interconnect line 1438. Suitable materials for electroless deposited overcoat layer 1434 include Ni, Co, Pd and Sn and their alloys, such as CoP and CoB, that are deposited using conventional electroless deposition techniques.

As depicted in FIG. 14D, a passivation layer 1439 is deposited on dielectric layer 1418 and on bond pad 1436 and contiguous interconnect line 1438, wherein layer 1439 includes materials similar to the materials of layer 444 shown in FIG. 4F. A schematic cross-sectional view of the structure illustrated in FIG. 14D along the lines X2-X2 is shown in FIG. 14E, depicting a cross-sectional view of bond pad 1436. It will be noted that the top surface of the bond pad comprises metal overcoat layer 1434 while the side and bottom surfaces of bond pad 1436 comprise barrier/seed sandwich layer 1412. Similarly, the top surface of interconnect line 1438 comprises metal overcoat layer 1434, while the side and bottom surfaces of the line comprises barrier/seed sandwich layer 1412, see FIG. 14C. The Cu material of the bond pad and the interconnect line is thus encased within the overcoat layer and the barrier/seed sandwich layer. It will be understood that the metal overcoat layer can extend (not shown) on exposed edge 1440 (FIG. 14C) of barrier/seed sandwich layer 1418.

Employing techniques similar to those used in connection with FIG. 5A, a passivation hole 1442 is formed in passivation layer 1439, as shown in FIG. 14F, thereby exposing a section 1444 of metal overcoat layer 1434 of novel bond pad 1436. A solder bump such as solder bump 530 (FIG. 5C) can be fabricated on bond pad 1436 inside passivation hole 1442. Alternatively, an Al plug can be formed in passivation hole 1442 shown in FIG. 14F, followed by the fabrication of an Al wire bond pad on the Al plug and on the passivation layer, similar to the materials and methods used in FIGS. 9A and 9B.

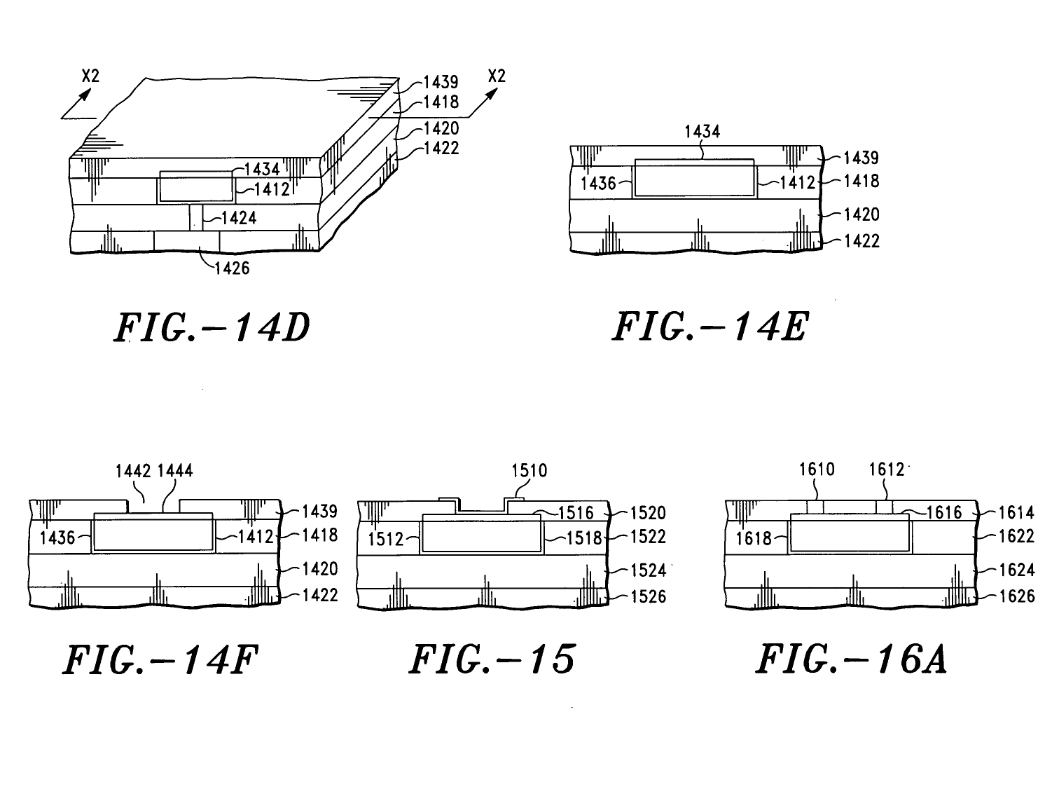

A structure similar to the one shown in FIG. 14F can be utilized to form a UBM 1510 on a bond pad 1512, depicted in FIG. 15, through the use of technologies that are described in connection with FIGS. 6A-6C. It is noted that components 1512, 1516, 1518, 1520, 1522, 1524 and 1526 shown in FIG. 15 are similar to components 1436, 1434, 1412, 1439, 1418, 1420 and 1422 respectively depicted in FIG. 14F. A solder bump such as solder bump 636 (FIG. 6D) can be formed on UBM 1510 shown in FIG. 15.

In an additional embodiment of the present invention, illustrated in FIG. 16A, a structure similar to the one shown in FIG. 14F can be employed in combination with techniques similar to those described in connection with FIG. 8A to form via holes 1610 and 1612 through passivation layer 1614. These via holes extend to overcoat layer 1616 of novel bond pad 1618. Components 1616, 1618, 1620, 1622, 1624 and 1626 shown in FIG. 16A are similar to components 1434, 1436, 1412, 1418, 1420 and 1422 respectively depicted in FIG. 14F while the materials comprising passivation layer 1614 (FIG. 16A) are similar to those of passivation layer 1439 (FIG. 14F). Subsequently, techniques similar to those described in connection with FIGS. 8B and 8C are utilized to form aluminum bond Al wire bond pad 1630 as shown in FIG. 16B. The wire bond pad is connected to overcoat layer 1616 of bond pad 1618 through Al via plugs 1632 and 1634 which are formed in via holes 1610 and 1612 respectively. The IC structure including novel Cu bond pad 1618, and Al bond pad 1630 comprises a novel duplex bond pad 1636 having novel Cu containing primary Cu containing pad 1618 and Al secondary pad 1630.

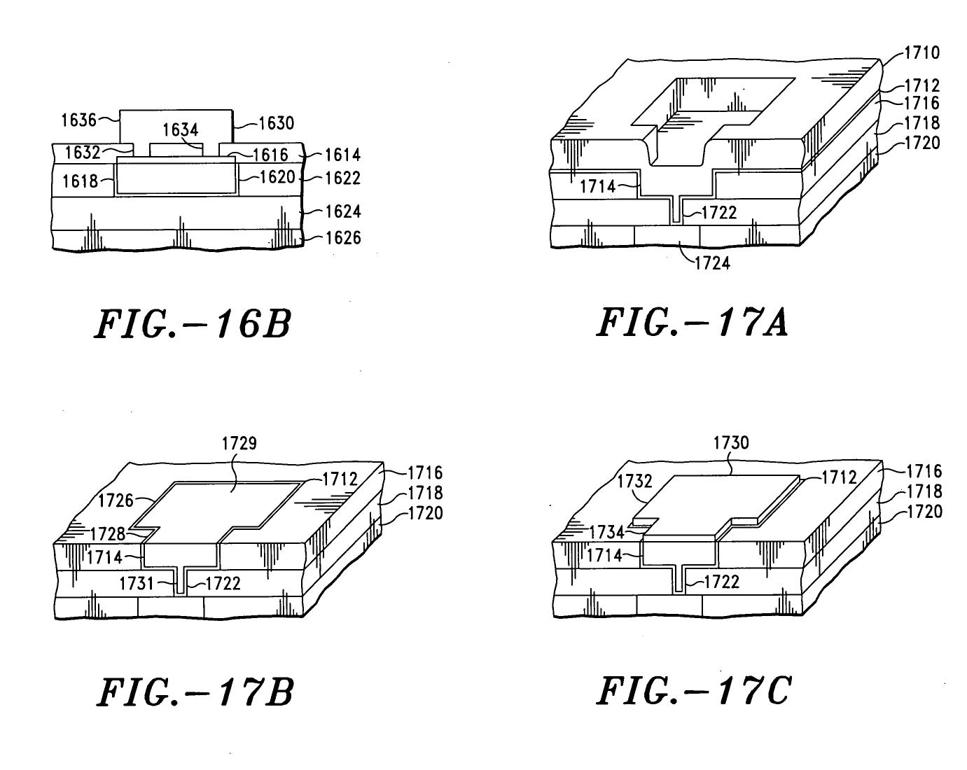

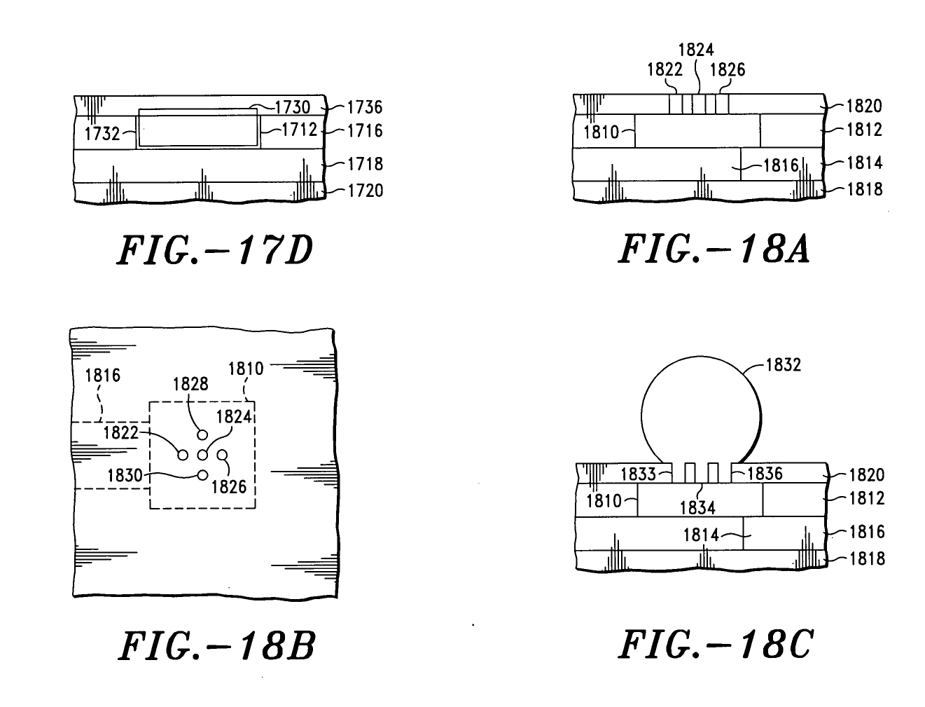

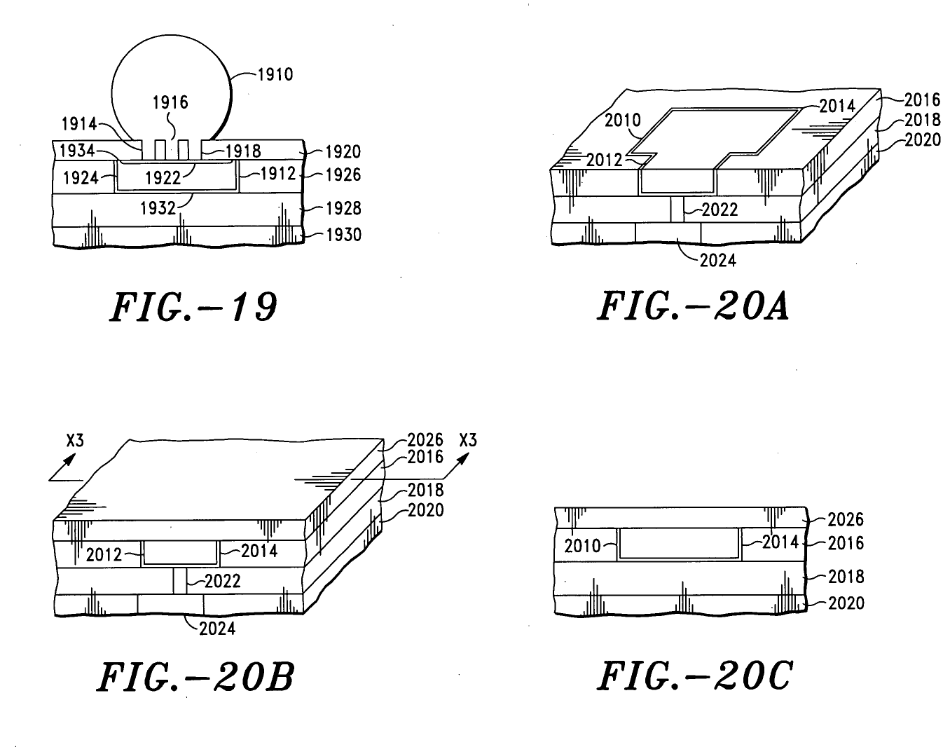

In further embodiments of the present invention FIG. 17A depicts a structure similar to the structure shown in FIG. 10C, but additionally including a substantially conformal Cu layer 1710 which is electroplated on an electrically conductive barrier/seed sandwich layer 1712. The conformal Cu layer is deposited in a cavity 1714 that is similar to cavity 1037 shown in FIG. 10C. Returning to FIG. 17A, the thickness of Cu layer 1710 is such that it forms an overfill of cavity 1714. Components 1712, 1714, 1716, 1718, 1720, 1722 and 1724 shown in FIG. 17A are similar to components 1036, 1037, 1012, 1010, 1014, 1034 and 1016 respectively depicted in FIG. 10C. Following CMP as described in connection with FIG. 15B, a Cu bond pad portion 1726 and a contiguous Cu interconnect line portion 1728 are defined in dielectric layer 1716 as illustrated in FIG. 17B. It is noted that the foregoing process results in a novel dual damascene structure 1729, depicted in FIG. 17B, including the simultaneously deposited novel bond pad portion 1726 and contiguous interconnect line portion 1728, and a via plug 1731. Then, an electroless metal overcoat layer 1730 is deposited on the Cu material of Cu bond pad portion 1726 and Cu interconnect line portion 1728, thereby forming a novel bond pad 1732 and a contiguous interconnect line 1734 as shown in FIG. 17C. Electroless metal overcoat layer 1730 comprises similar materials as layer 1434 shown in FIG. 14C. Using techniques and materials similar to those employed in connection with FIGS. 14D and 14E, a passivation layer 1736, depicted in FIG. 17D, is deposited on overcoat layer 1730 and dielectric layer 1716. The structure illustrated in FIG. 17D can be processed to form (1) a passivation hole on novel bond pad 1732 or (2) a UBM in a passivation hole on bond pad 1732 or (3) a novel duplex bond pad containing primary Cu containing pad 1732 and an Al secondary pad, wherein these fabricating processes can be executed using techniques and materials similar to those described and illustrated in connection with FIGS. 14F, 15 and 16B respectively.

As illustrated in FIGS. 8C and 16B, novel duplex bond pads are fabricated comprising a structure having a Cu containing primary pad and an Al secondary pad for wire bonding. The primary and secondary pads are separated by a passivation layer. An electrically conductive connection is made between the primary and secondary pads by means of via plugs through the passivation layer. FIGS. 8C and 16B are each shown as having two via plugs for making the connection. However, the use of two via plugs is merely exemplary since three or more via plugs formed in three or more via holes respectively are also suitable for embodiments of the present invention.

The techniques which are described in connection with embodiments of the present invention utilize photoresist masks. However, it will be understood that the invention is equally operable when hard masks or combinations of photoresist masks and hard masks are used. The various etching techniques and etching chemistries employed in the embodiments of the present invention include techniques and chemistries which are well known to those of ordinary skill in the art. Also, it will be understood that it is necessary to clean or prepare the surface of a structure prior to the deposition of any layer in any subsequent fabrication step, using surface preparation methods and materials which are well known to those of ordinary skill in the art. It will also be understood that methods for removing photoresist material and etch residue include conventional dry and wet methods.

While embodiments of the present invention are described, illustrated and exemplified by bond pads having a Cu layer such as Cu layers 438 (FIG. 4D), 1040 (FIG. 10D) and 1420 (FIG. 14A), the invention is also operable when a Cu alloy layer is used instead of a Cu layer. Suitable materials for a layer comprising Cu for fabricating a bond pad of the present invention thus include Cu and Cu alloys.

Wire bond pads of the present invention are illustrated and exemplified by Al wire bond pads such as wire bond pads 836 (FIG. 8C) and 930 (FIG. 9B). However, the invention is also operable when wire bond pads comprising Al alloy materials are employed.

Suitable passivation materials for passivation layers, such as layers 444 (FIG. 4G), 1052 (FIG. 10F) and 1440 (FIG. 14C) include silicon oxide, silicon nitride, oxynitride and dielectric polymers.

Suitable passivation layers also include sandwich layers wherein the layer contacting the bond pad overcoat layer includes SiN or SiC, followed by a silicon oxide containing layer. In the above described embodiments concerning Al deposition on the bond pad overcoat layer on bond pads of the present invention, it is also contemplated to employ a layer of Ti, TiW, Ta or TaN on the bond pad overcoat layer prior to Al deposition for fabricating the Al wire bond pad.

Suitable dielectric materials for dielectric layers wherein the novel bond pads and contiguous interconnect lines are formed, such as dielectric layer 400 (FIG. 4A), typically include silicon oxide. The expression “silicon oxide” as defined herein, includes SiO₂, related non-stoichiometric materials SiO_{X}. Related silica glasses include USG (undoped silica glass), FSG (fluorinated silica glass) and borophosphosilicate glass (BPSG). The expressions: “silicon oxide”, “related non-stoichiometric materials SiOₓ” and “related dielectric silica glasses”, as defined herein, exclude C-doped silicon oxide. Suitable dielectric materials for dielectric layers containing one or more vias that connect the pad interconnect line to a substrate such as an IC structure, for example dielectric layers 410 (FIG. 4A), 1010 (FIG. 10B) and 1310 (FIG. 13A) include materials having a low dielectric constant. These materials include C-doped silicon oxide such as partially oxidized organo silane materials containing at least 1% of carbon by atom weight, including oxidized organo silanes known as BLACK DIAMOND™ technology. Additionally other low dielectric constant materials are suitable for the via containing layer including polymers, for example amorphous fluorinated carbon based materials, spin-on dielectric polymers such as fluorinated and non-fluorinated poly(arylene) ethers (commercially known as FLARE 1.0 and 2.0, which are available from Allied Signal Company), poly(arylene) ethers (commercially known as PAE 2-3, available from Schumacher Company), divinyl siloxane benzocyclobutane (DVS-BCB) or similar products and aero-gel.

Advantageously, the inventive bond pad containing structures shown for example in FIGS. 4G, 5B, 6C, 8C, 9B, 10G, 11A, 14E, 14F, 15, 16B, 17C and 19 employ a novel Cu containing bond pad in order to benefit from the superior electrical conductivity of Cu compared with other pad materials such as Al. An inventive overcoat layer of electroless or electrolytically deposited metal such as Ni, Co, Pd, Zn and Sn and their alloys, such as CoP and CoB, provides enhanced adhesion between the pad and the passivation layer that is provided on a portion of the pad, as well as enhanced adhesion between the pad and a UBM. The enhanced adhesion between the Cu bond pad and the passivation layer additionally strengthens the dielectric stack that includes the inventive bond pad. The use of an overcoat layer on the inventive Cu pad and the contiguous interconnect line, as well as the use of a barrier/seed sandwich layer on the bottom surface and the side surfaces of the novel Cu pads illustrated in FIGS. 4G, 5B, 5C, 6B, 7B, 8C, 9A, 10F, 11B and 12 greatly reduce the potential for Cu diffusion into the adjoining dielectric layers. The greatly reduced potential for Cu diffusion results in improved electrical performance reliability of the inventive structures. The inventive overcoat layer also allows the use of a thinner UBM film than can otherwise be used. Additionally, it is contemplated to employ the overcoat layer instead of using a UBM.

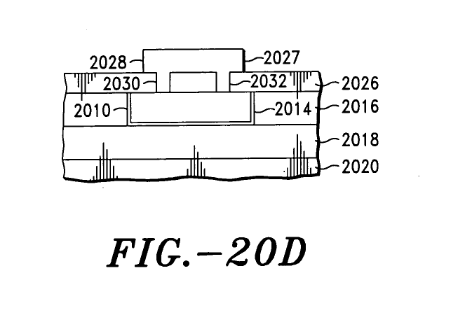

Embodiments of the present invention as described and shown in FIGS. 4F, 4G, 5A-5C, 6A-6D, 7A, 7B, 8A-8C, 9A, 9B, 10F, 10G, 11A, 11B and 12 employ Cu containing bond pads having an overcoat layer which results in an improved adhesion between the bond pad and the overlaying passivation layer. However, it is also contemplated to provide techniques for fabricating a novel interlock structure between a solder bump and a bond pad, as illustrated and described in connection with FIGS. 18A-18C and 19 to strengthen the bond pad stack.

As depicted in FIG. 18A, a bond pad 1810 is fabricated in a dielectric layer 1812 which is formed on a dielectric layer 1814 having an interconnect line 1816 which contacts pad 1810. Pad 1810 is connected to elements of an IC structure 1818 through interconnect line 1816. A passivation layer 1820 is deposited on dielectric layer 1812 having bond pad 1810. Multiple via holes, such as via holes 1822, 1824 and 1826 are formed through the passivation layer, thereby exposing sections of the top surface of the bond pad. In a different view of the structure shown in FIG. 18A, additional via holes 1828 and 1830 can also be provided through the passivation layer as depicted in FIG. 18B. A solder bump 1832, see FIG. 18C, is fabricated on passivation layer 1820 and in the via holes such as via holes 1822, 1824 and 1826, thereby forming solder bump plugs 1833, 1834 and 1836 respectively in these via holes.

In another embodiment of the present invention shown in FIG. 19, the techniques that are employed in fabricating the structures shown in FIGS. 18A-18C, can similarly be utilized to form a solder bump 1910 on bond pad 1912, by forming the solder bump in connection with simultaneously forming solder bump plugs 1914, 1916 and 1918 that are formed in passivation layer 1920. Bond pad 1912 comprises a bond pad of the present invention that includes a metal overcoat layer 1922 upon which solder bump plugs 1914, 1916 and 1918 are fabricated. The bond pad contacts an underlying IC structure by means of an interconnect line (not shown). It is noted that components 1912, 1922, 1924, 1926, 1928, 1930, 1932 and 1934 shown in FIG. 19 are similar to components 440, 439, 438, 400, 410, 414, 432 and 445 respectively depicted in FIG. 4G. It is further noted that overcoat layer 1922 does not completely cover the top surface of the Cu layer of bond pad 1912. Combining the techniques for forming the structures illustrated in FIGS. 14E and 19 a structure, similar to FIG. 19, is fabricated which is similar to FIG. 19 except that the metal overcoat layer covers the entire top surface of the Cu bond pad.

With reference to FIG. 18C, a novel interlock structure is formed which includes bond pad 1810, solder bump plugs 1832, 1834, 1836 and solder bump 1832. Similarly, with reference to FIG. 19, a novel interlock structure is formed which includes bond pad 1912, solder bump pad 1912 and solder bump plugs 1914, 1916 and 1918. These novel interlock structures provide enhanced structural integrity between the passivation layer and the bond pad, it also strengthens the dielectric stack that includes the bond pad. While embodiments of the present invention that are illustrated and described in connection with FIGS. 18A-18C and 19 employ three solder bump plugs to form the novel interlock structures, the invention is also operable when two, or more than three solder bump plugs are formed in the passivation layer. Preferably, at least three solder bump plugs are formed.

Novel duplex bond pads such as illustrated and described in connection with for example duplex bond pad 838 (FIG. 8C) and duplex bond pad 1632 (FIG. 16B) result in an Al wire bond pad having improved mechanical strength, as compared with conventional Al wire bond pads, due to the improved adhesion that is obtained between the passivation layer and the primary and secondary bond pads wherein the primary Cu bond pads employ a metal overcoat layer. The improved strength is particularly advantageous for resisting shear stresses that are exerted on the wire bond pad during wire bonding procedures. Also, the duplex bond pads of the present invention benefit from the use of Cu containing interconnects that have a greatly reduced potential for Cu diffusion into the dielectric stack.

Additionally, as illustrated in FIGS. 20A-20D novel duplex bond pads can be fabricated using a Cu bond pad without an overcoat layer. FIG. 20A shows a Cu bond pad 2010 and contiguous interconnect line 2012 which are similar to Cu bond pad portion 1430, and contiguous interconnect line portion 1432 respectively depicted in FIG. 14B. Returning to FIG. 20A, Cu pad 2010 and line 2012 are formed on a barrier/seed sandwich layer 2014. It is noted that components 2014, 2016, 2018, 2020, 2022 and 2024 shown in FIG. 20A are similar to components 1412, 1418, 1420, 1422, 1424 and 1426 respectively depicted in FIG. 14B. As shown in FIG. 20B, a passivation layer 2026 is deposited on Cu bond pad 2010 and contiguous line 2012, and on the exposed top surface of dielectric layer 2016. Passivation layer 2026 includes similar materials as passivation layer 1439 shown in FIG. 14D. A schematic cross-sectional view of the structure illustrated in FIG. 20B along the lines X3-X3 is shown in FIG. 20C, depicting a cross-sectional view of bond pad 2010. Then, following the procedures described and illustrated in connection with FIGS. 16A and 16B a novel duplex bond pad 2027, shown in FIG. 20D, is formed having Cu containing primary bond pad 2010 and an Al secondary bond pad 2028 for wire bonding, wherein the Al bond pad is fabricated on passivation layer 2026 such that the Al and Cu bond pads are connected by means of two or more via plugs, such as via plugs 2030 and 2032, that are fabricated through the passivation layer. Passivation layer 2026 supports Al bond pad 2028, particularly during wire bonding, resulting in a stronger dielectric stack than conventional dielectric stacks that are adapted for wire bonding.

Novel bond pads for wire bonding such as Al bond pad 930 (FIG. 9B) are fabricated on a passivation layer which is formed on a Cu bond pad having a metal overcoat layer. The overcoat layer improves the adhesion between an Al plug, that connects the Al bond pad, and an underlying Cu pad. The improved adhesion results in an improved mechanical strength of the dielectric stack, which is particularly beneficial during the wire bonding process. Preferred overcoat materials for bonding the Al plug to the Cu bond pad include Ni and Ni alloys. These overcoat materials can be deposited by means of conventional electroplating and electroless techniques.

The invention has been described in terms of exemplary embodiments of the invention. One skilled in the art will recognize that it would be possible to construct the elements of the present invention from a variety of means and to modify the placement of components in a variety of ways. While the embodiments of the invention have been described in detail and shown in the accompanying drawings, it will be evident that various further modifications are possible without departing from the scope of the invention as set forth in the following claims.

1. A method of forming a bond pad, the method comprising:
a) depositing a dielectric layer on a substrate;
b) depositing a photoresist layer on the dielectric layer;
c) forming an etch mask in the photoresist layer wherein the mask includes (1) a first mask section for etching a bond pad hole and (2) a second mask section for etching a trench, wherein the first and second mask sections are contiguous;
d) etching the first and second mask sections through the dielectric layer, wherein a bond pad hole and a contiguous trench are formed, such that the bond pad hole and the trench expose a section of the substrate; and
e) forming a layer comprising Cu, in the pad hole and in the trench, wherein a bond pad having a contiguous interconnect line is formed.

2. The method of claim 1 additionally comprising:
a) depositing a passivation layer on (1) the dielectric layer, (2) the bond pad and (3) the contiguous interconnect line; and
b) forming a passivation hole through the passivation layer such that the passivation hole exposes at least a portion of the bond pad.

3. The method of claim 1 wherein the substrate comprises a top layer including a C-doped silicon oxide material.

4. The method of claim 3 wherein the C-doped silicon oxide material comprises an oxidized organo silane matrial including an oxidized organo silane compound that is formed by reacting an organo silane compound with an oxidizing compound.

5. The method of claim 4 wherein the oxidized organo silane material comprises a carbon content of at least 1% by atomic weight.

6. The method of claim 5 wherein the oxidized organo silane material is formed by reacting an organo silane compound with N₂O gas at plasma conditions sufficient to form top the layer and wherein the plasma conditions additionally comprise:
a) a high frequency RF power density ranging from about 0.16 W/cm² to about 0.48 W/cm² for forming the layer; and
b) a sufficient amount of organo silane compound with respect to the N₂O gas to form the layer.

7. The method of claim 5 wherein the oxidized organo silane material is formed by reacting an organo silane compound with O₂ gas at plasma conditions sufficient to form the layer and wherein the plasma conditions comprise:
a) a high frequency RF power density greater than about 0.03 W/cm² for forming the layer; and
b) a sufficient amount of organo silane compound with respect to the O₂ gas to form the layer.

8. The method of claim 1 wherein the substrate comprises an IC structure.

9. The bond pad formed according to the method of claim 2.

10. A method of forming a wire bond pad, the method comprising:
a) depositing a first dielectric layer on an IC structure;
b) depositing a second dielectric layer on the first dielectric layer;
c) depositing a photoresist layer on the second dielectric layer;
d) forming an etch mask in the photoresist layer wherein the mask includes (1) a first mask section for etching a bond pad hole and (2) a second mask section for etching a trench, wherein the first and second mask sections are contiguous;
e) etching the first and second mask sections through the second dielectric layer, wherein a bond pad hole and a contiguous trench are formed, such the bond pad hole and trench expose a section of the first dielectric layer;
f) forming a layer comprising Cu, in the pad hole and in the trench, wherein a bond pad having a contiguous interconnect line is formed;
g) depositing a passivation layer on (1) the second dielectric layer, (2) the bond pad and (3) the contiguous interconnect line;
h) forming a passivation hole through the passivation layer such that the passivation hole exposes at least a portion of the bond pad;
i) depositing a plug comprising Al in the passivation hole; and
j) fabricating a bond pad comprising Al on the plug and on a portion of the passivation layer, thereby forming the wire bond pad.

11. The wire bond pad formed according to the method of claim 10.

12. A method of forming a duplex bond pad, the method comprising:
a) depositing a dielectric layer on an IC substrate;
b) forming a bond pad hole in the dielectric layer;
c) fabricating a Cu bond pad in the bond pad hole;
d) depositing a passivation layer on the dielectric layer including the bond pad;
e) forming at least two via holes in the passivation layer such that the at least two via holes expose at least a section of the Cu bond pad;
f) depositing an Al material into the two or more via holes, thereby forming two or more via plugs; and
g) fabricating an Al wire bond pad on the passivation layer and on the two or more via plugs, thereby forming a duplex bond pad wherein the Cu bond pad and the Al wire bond pad are connected through the two or more via plugs.

13. The duplex bond pad formed according to the method of claim 12.

14. A method of forming a duplex bond pad, the method comprising:
a) depositing a dielectric layer on an IC structure;
b) depositing a photoresist layer on the dielectric layer;
c) forming an etch mask in the photoresist layer wherein the mask includes (1) a first mask section for etching a bond pad hole and (2) a second mask section for etching a trench, wherein the first and second mask sections are contiguous;
d) etching the first and second mask sections through the dielectric layer, wherein a bond pad hole and a contiguous trench are formed, such that the bond pad hole and trench expose a section of the IC structure;
e) forming a layer comprising Cu, in the pad hole and in the trench, wherein a bond pad having a contiguous interconnect line is formed;
f) depositing a passivation layer on (1) the dielectric layer, (2) the bond pad and (3) the contiguous interconnect line;
g) forming at least two via holes through the passivation layer such that the via holes expose at least first and second sections of the bond pad;
h) forming via plugs comprising Al in the at least two via holes; and
i) fabricating a bond pad comprising Al on the via plugs and on a portion of the passivation layer, thereby forming the duplex bond pad.

15. The duplex bond pad formed according to the method of claim 14.

16. A method of forming a bond pad, the method comprising:
a) depositing a first dielectric layer on a first IC structure;
b) depositing a second dielectric layer on the first dielectric layer;
c) depositing a photoresist layer on the second dielectric layer;
d) forming an etch mask in the photoresist layer wherein the mask includes (1) a first mask section for etching a bond pad hole and (2) a second mask section for etching a trench, wherein the first and second mask sections are contiguous;
e) etching the first and second mask sections through the second dielectric layer, wherein the bond pad hole and the contiguous trench are formed, such that the bond pad hole and the trench expose a section of the first dielectric layer;
f) forming an electrically conductive liner in the bond pad hole and in the contiguous trench, thereby forming a lined pad hole and a lined contiguous trench;
g) forming a layer comprising Cu, in the lined pad hole and in the lined contiguous trench, such that the layer comprising Cu provides an underfill of the pad hole and the trench;
h) forming a metal overcoat layer on the Cu layer such that the metal overcoat layer provides an overfill of the pad hole and the trench, wherein a second IC structure is formed; and
i) planarizing the second IC structure to define a bond pad having (1) a bond pad top surface (2) an overcoat layer comprising at least 95% of the bond pad top surface and (3) a contiguous interconnect line having (i) a line top surface and (ii) an overcoat layer comprising at least 95% of the line top surface.

17. The method of claim 16 additionally comprising:
a) depositing a passivation layer on (1) the second dielectric layer, (2) the bond pad and (3) the contiguous interconnect line; and
b) forming a passivation hole through the passivation layer such that the passivation hole exposes at least a section of the bond pad.

18. The method of claim 16 wherein the first dielectric layer comprises a C-doped silicon oxide layer.

19. The method of claim 16 wherein forming the electrically conductive liner comprises forming a sandwich layer including:
a) depositing a substantially conformal Cu diffusion barrier layer in the pad hole and in contiguous trench; and
b) depositing a substantially conformal Cu seed layer on the Cu diffusion barrier layer.

20. The method of claim 16 wherein forming a metal overcoat layer is selected from the methods consisting of electroless metal deposition and electroplate metal deposition.

21. The bond pad formed according to the method of claim 16.

22. A method of forming a bond pad, the method comprising:
a) depositing a first dielectric layer on an IC structure;
b) depositing a second dielectric layer on the first dielectric layer;
c) employing etching techniques for etching (1) a pad hole and a contiguous trench through the second dielectric layer and (2) a via hole through the first dielectric layer, wherein the via hole connects the trench with the IC structure; and
d) employing a dual damascene technique for simultaneously forming (1) a via plug comprising Cu, (2) a bond pad comprising Cu and (3) a contiguous interconnect line comprising Cu.

23. The method of claim 22 additionally comprising:
a) depositing a passivation layer on (1) the second dielectric layer, (2) the bond pad and (3) the contiguous interconnect line; and
b) forming a passiviation hole through the passivation layer such that the passivation hole exposes at least a section of the bond pad.

24. The bond pad formed according to the method of claim 22.

25. A method of forming a bond pad, the method comprising:
a) depositing a first dielectric layer on a first IC structure;
b) depositing a second dielectric layer on the first dielectric layer;
c) employing etching techniques for etching (1) a pad hole and a contiguous trench through the second dielectric layer and (2) a via hole through the first dielectric layer, wherein the via hole connects the trench with the IC structure;
d) depositing an electrically conductive, substantially conformal Cu diffusion layer inside (1) the via hole, (2) the pad hole and (3) the contiguous trench;
e) depositing an electrically conductive, substantially conformal Cu seed layer on the Cu diffusion layer, wherein a lined via hole, a lined pad hole and a lined contiguous trench are formed;
f) employing a dual damascene technique for simultaneously forming a layer comprising Cu (1) inside the lined via hole (2) inside the lined pad hole, and (3) inside the lined contiguous trench, and wherein the layer comprising Cu includes an underfill of the pad hole and the trench;
g) forming a metal overcoat layer on the layer comprising Cu such that the overcoat layer comprises an overfill of the pad hole and the trench, wherein a second IC structure is formed;
h) planarizing the second IC structure to define a bond pad having (1) a bond pad top surface and (2) an overcoat layer comprising at least 95% of the top surface of the bond pad and (3) side and bottom surfaces that are formed in the lined pad hole;
i) depositing a passivation layer on (1) the surface of the second dielectric layer, (2) the bond pad and (3) the contiguous interconnect line, and
j) forming a passivation hole through the passivation layer such that the passivation hole exposes at least a section of the bond pad.

26. The method of claim 25 wherein forming a metal overcoat layer comprises an electroless deposition method.

27. The method of claim 25 wherein forming the metal overcoat layer comprises an electroplate deposition method.

28. The method of claim 25 wherein the first dielectric layer comprises a C-doped silicon oxide layer.

29. The method of claim 28 wherein the C-doped silicon oxide layer comprises an oxidized organo silane layer including an oxidized organo silane compound that is formed by reacting an organo silane compound with an oxidizing compound.

30. The method of claim 29 wherein the oxidized organo silane layer comprises a carbon content of at least 1% by atomic weight.

31. The bond pad formed according to the method of claim 25.

32. A method of forming a bond pad, the method comprising:
a) depositing a first dielectric layer on a first IC structure;
b) depositing a second dielectric layer on the first dielectric layer;
c) depositing a photoresist layer on the second dielectric layer;
d) forming an etch mask in the photoresist layer wherein the mask includes (1) a first mask section for etching a bond pad hole and (2) a second mask section for etching a trench, wherein the first and second mask sections are contiguous;
e) etching the first and second mask sections through the second dielectric layer, wherein the bond pad hole and the contiguous trench are formed, such that the bond pad hole and the trench expose a section of the first dielectric layer;
f) forming an electrically conductive barrier/seed liner in the bond pad hole and in the contiguous trench, thereby forming a lined pad hole and a lined contiguous trench;
g) forming a layer comprising Cu, in the lined pad hole and in the lined contiguous trench, such that the layer comprising Cu provides an overfill of the pad hole and the trench, wherein a second IC structure is formed;
h) planarizing the second IC structure to define (1) a bond pad portion including a bond pad Cu surface and (2) a contiguous interconnect line portion including a line Cu surface; and
i) employing an electroless metal deposition technique for depositing a metal overcoat layer on the Cu surface of the bond pad portion and on the Cu surface of the interconnect line portion, wherein a bond pad and contiguous interconnect line are formed.

33. The method of claim 32 additionally comprising:
a) depositing a passivation layer on (1) the bond pad, (2) the contiguous interconnect line and (3) the second dielectric layer; and
b) forming a passivation hole in the passivation layer such that the passivation hole exposes at least a section of the metal overcoat layer on the bond pad.

34. A third IC structure formed according to the method of claim 33.

35. A method for forming a solder bump, the method comprising:
a) forming a bond pad in a dielectric layer, such that the bump pad is exposed;
b) depositing a passivation layer on the bump pad and the dielectric layer;
c) forming a plurality of via holes through the passivation layer such that each of the plurality of holes exposes at least a section of the bond pad; and
d) simultaneously fabricating (1) via plugs in each of the plurality of via holes and (2) a solder bump formed on the via plugs.

36. The method of claim 35 comprising the bond pad additionally having (1) a top surface and (2) a metal overcoat layer, comprising at least 95% of the top surface, upon which the via holes are formed.

37. A structure comprising:
a) an IC structure;
b) a first dielectric layer deposited on the IC structure;
c) a second dielectric layer deposited on the first dielectric layer;
d) a bond pad fabricated in the second dielectric layer such that bond pad includes a contiguous interconnect line wherein the bond pad and interconnect line contact the first dielectric layer;
e) a passivation layer covering (1) the second dielectric layer, (2) the interconnect line and (3) the bond pad; and
f) a passivation hole through the passivation layer, such that the passivation hole exposes at least a portion of the bond pad.

38. The structure of claim 37 wherein the bond pad additionally comprises:
a) a bond pad top surface;
b) bond pad side and bottom surfaces;
c) a metal overcoat layer comprising at least 95% of the top surface; and
d) an electrically conductive barrier/seed sandwich layer that substantially covers the bottom and side surfaces.

39. The structure of claim 37 wherein the first dielectric layer comprises a C-doped silicon oxide layer.

40. A duplex bond pad comprising:
a) an IC structure;
b) a dielectric layer deposited on the IC structure;
c) a Cu bond pad formed in the dielectric layer;
d) a passivation layer deposited on the Cu bond pad and on the dielectric layer;
e) at least two via plugs formed through the passivation layer, wherein the at least two via plugs contact the Cu bond pad; and
f) an Al wire bond pad fabricated on (1) the passivation layer and (2) the at least two via plugs.
